(19) United States
(12) Patent Application Publication
(10) Pub. No.: US 2005/0251725 A1
(43) Pub. Date: Nov. 10, 2005

(54) Signal processing methods and systems

(75) Inventors: Jun Huang, Ottawa (CA); Yucong Miao, Kanata (CA); Xu Jiang, Ottawa (CA)

Correspondence Address: SMART & BIGGAR/FETHERSTONHAUGH & CO.;P.O. BOX 2999, STATION D, 900-55 METCALFE STREET, OTTAWA, ON, K1P5Y6, CA

(73) Assignee: GENIEVIEW INC.

(21) Appl. No.: 11/123,060

(22) Filed: May 6, 2005

Related U.S. Application Data
(60) Provisional application No. 60/568,251, filed on May 6, 2004.

(51) Int. Cl. G06F 11/00; G11C 29/00; H03M 13/00

(52) U.S. Cl. 714/752

(57) ABSTRACT

Signal processing systems and methods, illustratively for communication signals such as video communication signals, are provided. Adaptive interleaving systems and methods enable interleaving of information using different interleaving lengths. Encryption may also be combined with interleaving to control the position of information in an interleaved information stream. Corresponding de-interleaving and decryption systems and methods are also provided. An up-sampler and up-sampling method are provided for concealing errors in information. A new software defined radio architecture and associated methods, and software analysis techniques, are also disclosed. A communication system and management method integrate several of the above aspects for adapting communication operating characteristics to changing environments.

### CROSS-REFERENCE TO RELATED APPLICATION

This application is related to and claims the benefit of U.S. Provisional Patent Application Ser. No. 60/568,251, filed on May 6, 2004, and entitled “COMMUNICATION SIGNAL PROCESSING METHODS AND SYSTEMS”. The entire content of the provisional patent application, including specification and drawings, is incorporated into the present application by reference.

### FIELD OF THE INVENTION

This invention relates generally to signal processing and, in particular, to methods and systems for performing interleaving, encryption, error concealment, and other types of signal processing.

### BACKGROUND

With the past surge of the commercialization of the Internet, the continuing expansion of wireless services, and the increasing usage of multimedia applications, communication traffic demand has seen a steady increase. Researchers are diligently working towards disruptive technology that has not previously been given substantial attention, including narrowband wireless video applications, underwater acoustic imaging, and software defined radio applied to public safety, for example.

The response from the engineering world for new application opportunities is two-fold. One involves expanding the transmission bandwidth, pushing the envelope of broadband, while the other involves reducing the application bandwidth, pushing the limits of compression. Bandwidth reduction for video applications, for example, while maintaining the quality of the video at the same time, may be particularly challenging. Communication link issues such as wireless link errors and Internet congestion introduce further concerns, as compressed video is very vulnerable to any error or loss.

Wireless communication is narrowband because of limited spectrum allocation from the FCC in the USA, or equivalent radio regulation organizations for other countries. Another reason is noise and interference—the longer the propagation path, the more the noise is accumulated along the way from transmitter to the receiver.

Underwater acoustic communication links are also narrowband, because of the limited overall spectrum, about several Megahertz in total. High frequency sound does not propagate far in water [Stojanovic]. Using communication with modulation on a 1 MHz carrier, for instance, the typical information rate can only be 115.2 Kbps. Throughput is even further reduced for greater distances.

Wired networks have limited bandwidth, because the “last mile” local loop to the home/office typically has a load coil which was installed a few decades ago for improving voice quality, with voice typically occupying the 3 kHz band. ADSL (Asymmetric Digital Subscriber Line) has high speed for download only. The upload return path is still limited in bandwidth. The same is true for cable modems. Broadband communications can hardly be realized for even slightly remote areas around a city, not to mention outside urban areas.

Satellite communications are also narrowband. Because the typical GeoStationary satellite is 36000 km away from the earth, signal strength is very weak by the time a signal reaches the earth, and white noise in the receiver itself can cause a problem for recovering the satellite signal [Bruce]. The same problem is encountered in terrestrial microwave system. Throughput drops when the distance increases.

Even if we have certain forms of terrestrial broadband wireless (DVB-T), Cable modem (DVB-C), ADSL, Advanced Satellite (DVB-S), we may still experience low throughput when the backbone network has congestion. This happens very often over International links. The above-mentioned problems are not expected to be solved within the near future.

Although studies have been done in the field of transmitting video over wired media and wireless media, research that addresses both wired and wireless communications is still lacking. One such study proposed to use an interleaving mechanism to solve the above problems. However, single layer fixed interleaving is not enough to combat the impairment introduced by both the error-prone wireless link [Muharemovic] and the loss-prone Internet path [Claypool].

As a consequence, the task of searching for a method of reducing overall impairment to video streams over both wireless and Internet links remains urgent.

Some studies have already been done on the GPRS (General Packet Radio Service) and 3G/4G forums for wireless loss [Chakravorty] and error [STRIKE]. However the problem cell phone users are facing is different than those associated with video and other broadband communications. The typical cell phone call lasts a few minutes, and the chance it gets error and congestion is also low. However, for public safety and other video monitoring applications, for example, the expectation is that a link should stay up for a few hours or even around the clock.

Traditional techniques for reducing error can be categorized into two main fundamental schools, including one focused on the transmission physical layer [Robert], or so-called channel coding [Masami], and the other on the application layer, or so-called source coding. More or less, these two schools of studies are using completely different methods and little co-ordination can be made across the layers.

Some studies do consider both source coding and channel coding, and proposed so-called conditional retransmission [Supavadee] or scalable encoding [He]. Due to the complexity in the implementations of these schemes, no commercial chip is currently available.

In respect of source coding, a number of error concealment and resilient algorithms have been reported [Raman].

For channel coding, many researchers are using Interleaver [Cai], or adaptive [Ding] or concatenated Forward Error Coding (FEC) schemes such as Turbo coding [Hanzo] to approach the error correction limit. With complicated soft iterative decoding algorithms, the Shannon limit can be approached within less than 0.1 dB ranges. By applying different puncturing patterns, a different coding rate k/n can be achieved in practice, where k is a number of user information bits, and n is the total number of bits coded.

A new LDP (Low Density Parity) code has recently been proposed [Amir]. This code has better performance, but the implementation is fairly complicated, needs either a dedicated ASIC (Application Specific Integrated Circuit) or an expensive and powerful DSP (Digital Signal Processing) engine. The cost of ASICs tends to go down only for large quantities as time goes by. In non-telecom and non-consumer markets, volume generally does not justify dedicated ASIC implementations. High power DSPs also tend to consume power that is beyond current battery capability for many mobile devices, such as communication devices supporting multiband flexible software defined radio [Barbeau] expected to be used in public safety applications, for example.

Many researchers have moved on to the space domain from the time domain, studying the possibility of using time-space coding [Vucetic] to take advantage of antenna diversities—the space resource. Although this approach is promising, cost increases with an increased number of antennas. Additional computation-intensive processing is also required in order to make use of multipaths that exist in certain environments for certain frequency ranges.

This method is arranged on the evolution path of OFDMA (Orthogonal Frequency Division Multiple Access) [Hatim], but the price of the radio and regulation is preventing quick market roll-out, especially for handheld products for moderate volume production. The main pressures affecting this approach include competition from CDMA (Code Division Multiple Access), and perhaps UWB (Ultra-Wide Band) in the future.

As will be apparent from above, little headroom remains to develop the two kinds of coding separately. Most vendors simply take Commercial Off The Shelf (COTS) modules and “glue” them together, leaving no space for coordinating source coding with channel coding at all.

Various issues which complicate the use of narrowband communication links to transfer broadband communication signals thus remain to be resolved.

### SUMMARY OF THE INVENTION

According to one aspect of the invention, there is provided an interleaving system which includes an input for receiving information and a plurality of interleavers operatively coupled to the input in an interleaving path. The interleavers have respective associated interleaving lengths and are configured to interleave the received information according to their respective associated interleaving lengths to provide an aggregate interleaving length for the interleaving path.

The system may also include a controller configured to control whether each of the interleavers is active in the interleaving path to interleave the received information. The controller may control whether each of the interleavers is active based on a type of the received information, so as to provide a first aggregate interleaving length where the information comprises still images and a second aggregate interleaving length shorter than the first interleaving length where the information comprises video, for example.

In some embodiments, the system includes a receiver operatively coupled to the controller and configured to receive control information. The controller may then control whether each of the interleavers is active based on the received control information. The control information may include monitored communication link information for a communication link over which the information is to be transmitted and/or a command to activate an interleaver having a particular associated length.

The interleaving lengths of the interleavers may follow a discrete Fractal distribution.

The interleavers may include interleavers which are respectively associated with different layers in a layered architecture.

The interleaving system may be implemented, for example, in a communication device which is configured to transmit interleaved information. The communication device may also include a transmitter operatively coupled to the interleaving system for transmitting the interleaved information to a remote system, a receiver configured to receive control information from the remote system, and a controller operatively coupled to the interleaving system and to the receiver, and configured to control whether each of the plurality of interleavers is active in the interleaving path to interleave the received information based on the control information received from the remote system.

According to another embodiment, the system includes an input for receiving security information. In this case, the interleavers may include at least one interleaver which is further configured to interleave the information based on the received security information.

A de-interleaving system is also provided, and includes an input for receiving interleaved information, and a plurality of de-interleavers operatively coupled to the input in a de-interleaving path. The de-interleavers have respective associated de-interleaving lengths and are configured to de-interleave the received interleaved information according to their respective associated de-interleaving lengths to provide an aggregate de-interleaving length for the de-interleaving path.

The de-interleaving system may also include an input for receiving security information, with the de-interleavers including at least one de-interleaver which is further configured to de-interleave the received interleaved information based on the received security information.

A controller may also be included in the de-interleaving system to control whether each of the plurality of de-interleavers is active in the de-interleaving path to de-interleave the received interleaved information. The controller may determine an interleaving length used at a source of the received interleaved information, and control the de-interleavers to provide an aggregate de-interleaving length corresponding to the interleaving length.

A further aspect of the invention provides a method of processing information. The method involves receiving information over a communication link, analyzing the received information to determine conditions on the communication link, and interleaving information to be subsequently transmitted on the communication link using an adapted interleaving length, the adapted interleaving length being determined on the basis of the determined conditions.

The operation of analyzing may include determining whether the information comprises an expected sequence value.

The method may also include detecting congestion of the communication link and determining the adapted interleaving length responsive to detecting congestion.

In another embodiment, the method includes receiving information to be transmitted on the communication link, interleaving the information to be transmitted using the adapted interleaving length, and transmitting on the communication link the interleaved information and an indication of the adapted interleaving length.

According to another aspect of the invention, there is provided an interleaving system which includes an input for receiving information, an input for receiving security information, and at least one interleaver configured to receive the information and the security information, and to interleave the received information using the received security information. The at least one interleaver controls respective interleaved positions of portions of the received information based on the received security information.

The at least one interleaver may include a plurality of interleavers configured to interleave the received information based on respective portions of the received security information.

A related de-interleaving system includes an input for receiving interleaved information, an input for receiving security information, and at least one de-interleaver configured to receive the interleaved information and the security information, and to de-interleave the received interleaved information using the received security information, the at least one de-interleaver controlling respective positions of portions of the received interleaved information in a de-interleaved data stream based on the received security information.

A method of encrypting information is also provided, and involves receiving information, receiving an encryption key, and interleaving the received information based on the encryption key to generate interleaved information, the respective interleaved positions of a plurality of portions of the received information in the interleaved information being determined by the encryption key.

A further aspect of the invention provides an up-sampler for concealing errors in a damaged block of information of an information stream comprising a plurality of blocks of information. The up-sampler is configured to determine a distance between the damaged block and an undamaged block of information in the information stream, and to apply to the undamaged block a weight based on the distance to interpolate the damaged block, wherein the weight is one of a plurality of weights which follow a Fractal distribution proportional to the distance.

The blocks may be blocks of a video signal. In this case the up-sampler may apply a weight by applying the weight to picture information in the undamaged block.

Where the undamaged block includes a motion vector, and the up-sampler may apply a weight by applying the weight to the motion vector. The motion vector may be a motion vector associated with a location within the undamaged block, and applying may involve determining a motion vector V(x,y) in the damaged block as
V(x,y)=alpha(i)*V(x−i,y)+alpha(i)*V(x+i,y),
where alpha is the weight and “i” is the distance.

In some embodiments in which the blocks are blocks of a video signal, a Fractal index of the Fractal distribution depends on at least one of: a type of the video signal and an amount of motion present as indicated in a motion vector of the blocks.

The up-sampler may be implemented, for example, in conjunction with a video signal.

An up-sampling method for concealing errors in a block of information in an information stream, according to yet another aspect of the invention, includes determining a distance between a damaged block and an undamaged block of information in the information stream, selecting a smoothing factor from a plurality of smoothing factors based on the distance, the plurality of smoothing factors following a Fractal distribution proportional to the distance, and applying the selected smoothing factor to the undamaged block to interpolate the damaged block.

A software defined wireless communication radio architecture may also be provided. This architecture may include a communication device component for implementation at a mobile wireless communication device, and a central device component for implementation at a central system with which the wireless communication device is configured to communicate.

A related method of providing a software defined wireless communication radio may include operations such as providing a communication device software component at a mobile wireless communication device, and providing a central device component at a central system with which the wireless communication device is configured to communicate.

A method of analyzing software interactions may include such operations as identifying software objects which interact, identifying messages the software objects exchange, with corresponding calls being identified by method signatures, and identifying a control flow and corresponding conditions involved in interactions between the software objects.

A run-time method of analyzing software code may include generating an execution trace, applying consistency rules to the execution trace, and generating a sequence diagram from the execution trace and the consistency rules.

In a communication system in which a central communication device configured to communicate with each of at least one mobile communication device, the central communication device may determine a current communication environment between the central device and each mobile device, and control an operating mode of each mobile device depending upon the current communication environment.

A related method of managing communications between a central communication device and a plurality of remote mobile communication devices may include determining, at the central device, a current communication environment between the central device and each mobile device, and controlling an operating mode of each mobile device depending upon the current communication environment.

Other aspects and features of embodiments of the present invention will become apparent to those ordinarily skilled in the art upon review of the following description of the specific embodiments of the invention.

### BRIEF DESCRIPTION OF THE DRAWINGS

Examples of embodiments of the invention will now be described in greater detail with reference to the accompanying drawings, in which:

FIG. 1 is a block diagram of a system according to an embodiment of the invention.

FIG. 2 is a block diagram illustrating a video information format used by an embodiment of the invention.

FIG. 3 is a block diagram of a communication device incorporating an interleaving system according to an embodiment of the invention.

FIG. 4 is a block diagram of a communication device incorporating a de-interleaving system according to an embodiment of the invention.

FIG. 5 is a block diagram of an illustrative example interleaving system of an embodiment of the invention.

FIG. 6 is a block diagram of an illustrative example de-interleaving system of an embodiment of the invention.

FIG. 7 is a flow diagram of a method according to an embodiment of the invention.

FIG. 8 is a scenario diagram of a model according to an embodiment of the invention.

FIG. 9 is a trace diagram of a model according to an embodiment of the invention.

FIG. 10 is a pseudo code of an algorithm according to an embodiment of the invention.

FIG. 11 is a block diagram of a terminal according to an embodiment of the invention.

FIG. 12 is a block diagram of a server according to an embodiment of the invention.

FIG. 13 is a block diagram of a client system according to an embodiment of the invention.

FIG. 14 is a block diagram of an application according to an embodiment of the invention.

FIG. 15 is a block diagram of another application according to an embodiment of the invention.

FIG. 16 is a circuit diagram of a terminal according to an embodiment of the invention.

### DETAILED DESCRIPTION OF PREFERRED EMBODIMENTS

Cross-layer error correction techniques are provided according to one broad aspect of the invention, and may be used on top of such solutions as FEC coding and error concealment schemes to reduce errors.

One innovation involves extending interleaving and error concealment to a multi-layer, preferably Fractal, concept to relieve the effects of both wireless error and network congestion. As will become apparent, the multi-layer concept may be used in communication devices to enable real-time transfer of video communications over narrowband communication links. In some embodiments, adaptive runtime algorithms and in-circuit measurements are also used within a new distributed software defined radio architecture setting, to provide improved video quality over various narrowband communication systems, including underwater, on land and in deep space.

According to a particular embodiment of the invention, interleave length, instead of coding rate, is adjusted to effectively reach a compromise between theoretical performance and difficulty of actual implementation. For example, interleaver gain over air space may be varied by using the methodology of matching the structure of a multi-layer interleaver with that of the wireless link error. The mechanism can be used to achieve substantially similar matching between interleaver gain and other types of error, such as congestion-caused “burst error”. This is a novel combination approach to improving long distance video quality, and the feasibility of broadband communications in band-limited communication systems.

Both of these matches may lead to a Fractal structured multi-layer interleaver where the length of the each interleaver follows a discrete Fractal distribution. The parameters of interleaving can be adjusted according to environment. Due to the statistical character of Internet Protocol (IP) traffic, for example, the chance of having both burst error on a wireless link and congested forward Internet is small. With adaptive schemes as disclosed herein, there is no need to lock a static design to the worst case.

The active coordination involving the training and the on-the-fly dynamic changing of interleaver parameters automates initial deployment of a system and is self-adjusting throughout its lifetime.

Although wired and wireless links represent examples of communication links to which embodiments of the invention may be applied, it should be appreciated that the invention is in no way limited to coping with common types of wired and wireless links only. If desired, embodiments of the invention may be used to improve video quality for other less common types of communication link, such as those used in underwater communications, legacy satellite systems, and advanced deep space communications, for example. Illustrative example systems to which the invention may be adapted include satellite systems such as LEO (Low Earth Orbit), MEO (Medium Earth Orbit), GEO (Geostationary Earth Orbit), HEO (Highly Elliptical Orbit), Stratospheric Balloon or Helicopter, and other systems such as terrestrial communication systems, including Personal Area Networks, Microwave, Cellular, or any combinations thereof.

Embodiments of the invention disclosed herein may also be useful for future deep space communication, where the neutrino will be used to carry information, bandwidth will be more limited, and noise experienced may have an astronomically long burst.

The principles disclosed herein are also substantially independent of system architecture, and may be used for virtually all network architectures, including P2P (Point-to-Point), PMP (Point-to-Multi-Point), or mesh architecture, for instance.

The invention is also insensitive to the access method, and may be applied to TDMA (Time Division Multiple Access), FDMA (Frequency Division Multiple Access), MF-TDMA (Multi-Frequency TDMA), or any other access method.

Similarly, the invention is insensitive to a duplexing method, and can be employed for TDD (Time Division Duplexing), FDD (Frequency Division Duplexing), or any other duplexing method.

FEC for wireless communications is usually done with fixed coding length, assuming some typical error pattern over the air. In reality, the RF (Radio Frequency) environment changes, especially for mobile and semi-mobile cases. In a semi-mobile video surveillance application, for example, communications might normally take place between an on-duty authority holding a portable camera and his/her partner in a service truck/car receiving streaming real-time video and/or still images. The video information is further forwarded to a fixed center through the Internet. The error pattern [Xueshi] on the wireless link can change dramatically depending on where the car is parked, and where the camera is moved.

The loss pattern [Yu] on the Internet link can change dramatically depending on the transfer path of the image, and its final destination.

On the other hand, sending still pictures and sending live streaming video also have different requirements on error correcting capability for particular error patterns. As a consequence, fixed interleaving might not generally offer the best performance for video and other types of information.

One basic rule which could be implemented in accordance with an embodiment of the invention is when sending still pictures, use a relatively long interleave, and when streaming video, use a shorter interleave. A set of a number of layers and an interleave length on each layer may be defined to fit different picture size, frame rate, data rate, and wireless and Internet environment type conditions.

For example, Packet/Frame level interleaving may be used on top of Bit/Byte level interleave when a packet is being transferred through a WAN (Wide Area Network).

A small database may also be constructed to learn and set the optimized interleave size and dimension.

Different error recovery algorithms on an MPEG (Moving Pictures Experts Group) layer may similarly have different sensitivities to different types of error. Thus, an error recovery algorithm may also be switched to match interleave length.

Packet loss patterns on the Internet change as well, depending on the path of the packet. As such, this factor may be taken into consideration as well. Multi-dimensional decisions may be made to optimize the size and dimension of interleaving. As used herein, interleaver dimension refers to the number of levels of an interleaver. Thus, an interleaver in which both byte and bit interleavers are used, is referred to primarily as a two dimensional interleaver. The size of each interleaver is referenced by its corresponding unit, such that a byte interleaver of size n interleaves n bytes for instance. Either or both of the dimension and the size may be adjusted in accordance with an aspect of the invention, for matching with a current operating environment of a wireless communication device, for example.

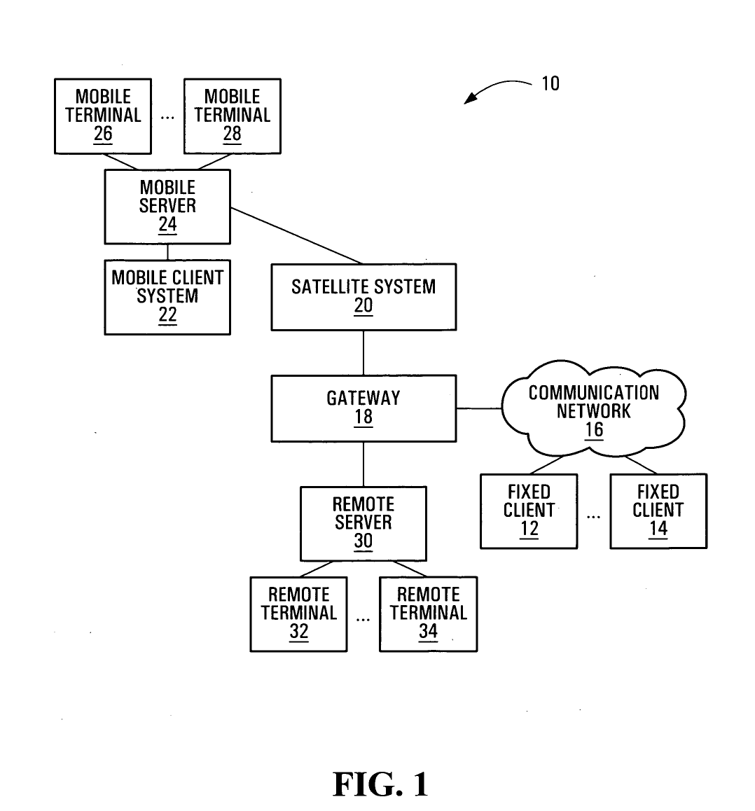

Referring now in detail to the drawings, FIG. 1 is a block diagram of a system according to an embodiment of the invention. The system 10 represents an example network system architecture in which the signal processing techniques disclosed herein may be applied to communications between terminals and client systems, to coordinate error correction in different layers, for example.

In terms of its general high-level structure, the system 10 is a typical Point-to-Multi-Point (PMP) network, including fixed client systems 12, 14 operatively coupled to a gateway 18 through a communication network 16. The gateway 18 is operatively coupled to a mobile server 24 through a satellite system 20, and also to a remote server 30. The mobile server is operatively coupled to mobile communication devices, including a mobile client system 22 and mobile terminals 26, 28. The remote server 30 is operatively coupled to remote terminals 32, 34.

It should be appreciated that the particular components and system topology shown in FIG. 1 are intended solely for illustrative purposes. The present invention is in no way limited to any particular type of communication device or system. Embodiments of the invention may be implemented in communication having further, fewer, or different components with different interconnections than those shown in FIG. 1. In addition, some embodiments of the invention may be implemented at a particular device, whereas other embodiments involve components or modules which are implemented at multiple locations.

FIG. 1, as well as the other Figures, should thus be interpreted accordingly, as illustrative and not limiting.

Those skilled in the art will be familiar with many different types of equipment which may be used to implement the various components of the system 10, and accordingly these components are described only briefly herein to the extent necessary to appreciate embodiments of the invention.

The fixed client systems 12, 14, for example, represent computer systems or other devices which may be used to access information collected by any or all of the terminals 26, 28, 32, 34. Information access by the client systems 12, 14 is through the communication network 16 and the gateway 18. In one embodiment, the communication network 16 is the Internet, although implementation of embodiments of the invention in conjunction with other networks is also contemplated. The types of connections between the fixed client systems 12, 14 and the gateway 18 through the communication network 16 will be dependent upon the type of the communication network 16. Although only one network 16 is explicitly shown in FIG. 1, multiple networks of similar or distinct types may be provided in some embodiments.

Although shown in FIG. 1 as network connections through the communication network 16, client to gateway connections may instead be direct connections. Similarly, the representation of other connections in the system 10 as direct connections should not be interpreted narrowly. Each of these connections may instead be indirect connections which traverse other networks or communication equipment.

The gateway 18 may be a fixed central headquarters for managing information collected by the terminals 26, 28, 32, 34, and also bridges the communication network 16 to the mobile and remote servers 24, 30. The servers 24, 30, described in further detail below, represent control centers which are operatively coupled to the gateway 16 for managing communications with the terminals 26, 28, 32, 34, mobile client systems such as the mobile client system 22, and remote client systems (not shown).

Considering first the mobile server 24, the communication link between the gateway 18 and the mobile server 24 is provided through the satellite system 20, and may be a Ku band satellite communication link, for example. Other types of communication link, including both wired and wireless communication links, may be provided between the gateway 18 and the mobile server 24. Where multiple mobile servers are provided to service client systems and terminals in different wireless communication systems for instance, each mobile server may use the same or a different type of connection with the communication network 16.

The mobile server 24 preferably allows the mobile client 22 to perform substantially the same functions as the fixed client systems 12, 14. The mobile client system 22 may thus be substantially similar to the fixed client systems 12, 14, a laptop computer system for instance. For a mobile client, however, a communication link with the mobile server 24 is, or at least includes, a wireless connection.

The mobile terminals 26, 28 are preferably devices which collect information for transfer to the mobile server 24, and may also receive information from the mobile server 24. In one embodiment, the mobile terminals 26, 28 are wireless communication devices which incorporate video cameras for surveillance purposes.

Although not explicitly shown in FIG. 1, wireless communication links between the mobile client system 22, the terminals 26, 28, and the mobile server 24 would in many embodiments be provided through one or more wireless communication networks. Examples of such wireless communication links include 1.9 GHz GPRS connection, 3.5 GHz access connections, 900 MHz connections, 430 MHz connections, 1.8 GHz CDMA connections, 2.4 GHz connections, and possibly other types of connection which will be apparent to those skilled in the art.

The remote server 30 provides a substantially similar function as the mobile server 24, but for the remote terminals 32, 34. The remote terminals 32, 34, like the mobile terminals 26, 28, may include information collection devices such as video cameras. Remote clients (not shown) may also be serviced by the remote server 30. As the mobile server 24 handles mobile wireless terminals and clients, connections between the remote server 30 and other components of the system 10, including the gateway 16 and the remote terminals 32, 34, may be wired connections in many embodiments. Examples of wired connections include power line carrier connections at 10 MHz for instance, dial up connections, ADSL, cable modem, or other high speed connections, 1 MHz acoustic connections, and star particle link connections. Other types of connection will be apparent to those skilled in the art.

In operation, the terminals 26, 28, 32, 24 collect information, illustratively video surveillance information, and transmit this information, preferably in real time, to their respective servers 24, 30. The servers 24, 30 may store the received information locally, transmit the information to the gateway 18 for storage in a central store (not shown) or relaying to client systems, or both. The information collected by the terminals 26, 28, 32, 34 may be accessed by or transmitted to any of the client systems 12, 14, 22. The actual transfer, possible storage, and access of information may be substantially in accordance with conventional techniques, although embodiments of the invention improve various aspects of these operations, particularly for band-limited connections.

For example, where the mobile terminal 26 is collecting JPEG (Joint Photographic Experts Group) images, it may be controlled to use a long interleave length for transmitting the images to the mobile server 24. The terminal 28, on the other hand, may be collecting and streaming MPEG video to the mobile server 24 using a shorter interleave length.

By matching the upper layer application profile with the lower layers transmission profile and transport profiles in this manner, and adaptively, the performance for each application can be enhanced without compromising for a “one-fit-all” low layer algorithm.

From a hand-shaking point of view, processing load for adaptive matching may be handed off to equipment at the central side of the system 10, such as the servers 24, 30. Typically, central equipment has more processing, power, and other resources than remote or mobile terminals. With centrally managed adaptation, a mobile or remote terminal 26, 28, 32, 34 may lose synchronization with central equipment when switching over between different modes, and thus both sides may switch to a default or basic mode, in case of failure of the transition. Reversion to a “basic” mode may involve using traditional processing techniques instead of adaptive techniques.

A basic or default mode is preferably always available for all layers, such as when central equipment is not able to find out the best match for particular current operating conditions.

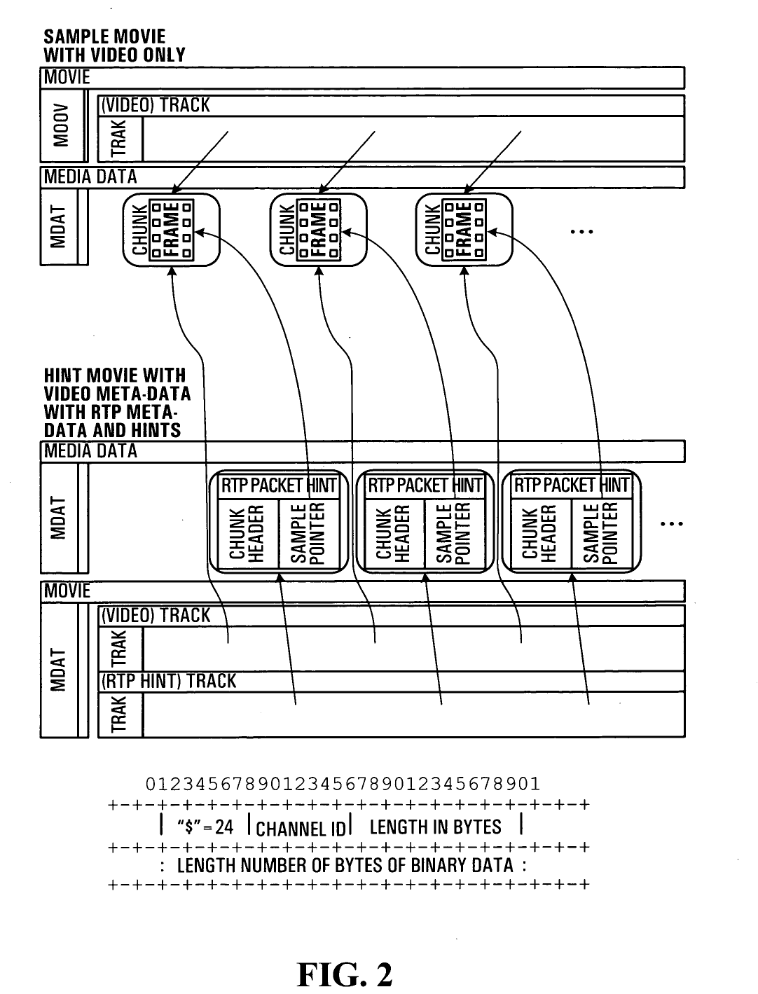

Before describing embodiments of the invention in further detail, it may be useful to first review the basic concept of the MPEG4 video format, which is illustrated in FIG. 2 and may be used by embodiments of the invention.

The MP4 file format is designed to contain the media information of an MPEG-4 presentation in a flexible, extensible format which facilitates interchange, management, editing, and presentation of the media information. This presentation may be ‘local’ to the system containing the presentation, or may be via a network or other stream delivery mechanism (a TransMux). The file format is designed to be independent of any particular delivery protocol while enabling efficient support for delivery in general.

The MP4 file format is composed of object-oriented structures called ‘atoms’. A unique tag and a length identify each atom. Most atoms describe a hierarchy of metadata giving information such as index points, durations, and pointers to the media data. This collection of atoms is contained in an atom called the ‘movie atom’. The media data itself is located elsewhere; it can be in the MP4 file, contained in one or more ‘mdat’ or media data atoms, or located outside the MP4 file and referenced via URL's.

As can be seen in FIG. 2, MPEG4 is such a highly structured encoding format, missing one byte or even one bit, over a wireless link for instance, can destroy the whole structure, and cause problems during playback at a receiver.

Traditional FEC can reduce error rates, but at the cost of increased bandwidth. According to an embodiment of the invention, error rates are improved without incurring bandwidth overhead using interleaving techniques.

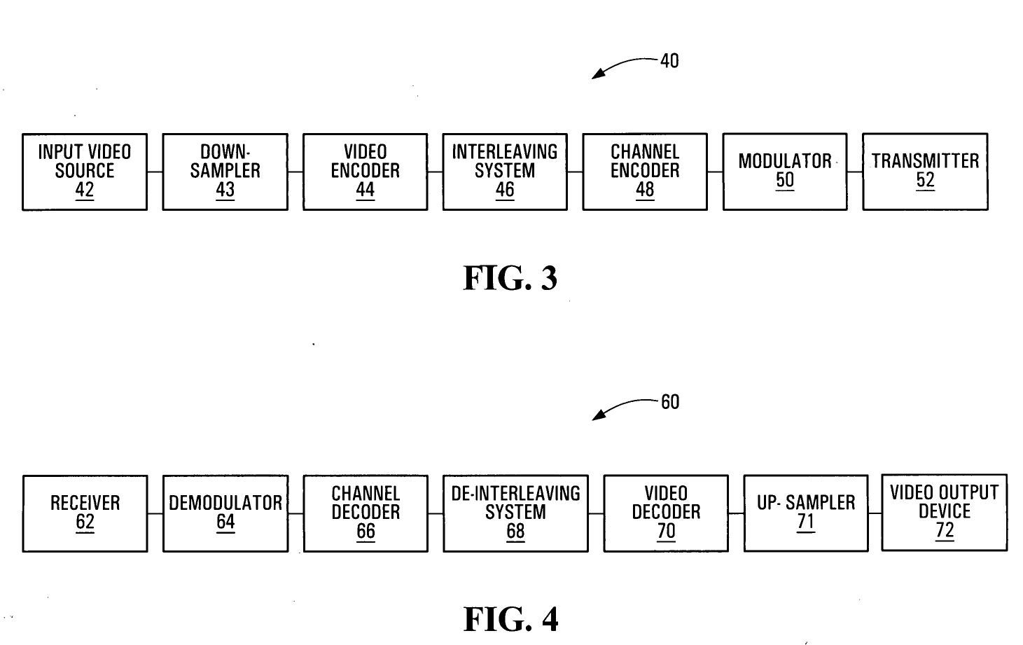

FIG. 3 is a block diagram of a communication device incorporating an interleaving system according to an embodiment of the invention. The device 40 includes an input video source 42, such as a video camera, a down-sampler 43 operatively coupled to the input video source 42, a video encoder 44, illustratively an MPEG4 encoder, operatively coupled to the down-sampler 43, an interleaving system 46 operatively coupled to the video encoder 44, a channel encoder 48 operatively coupled to the interleaving system 46, a modulator 50 operatively coupled to the channel encoder 48, and a transmitter 52 operatively coupled to the modulator 50.

Although the input video source 42 would normally be implemented using hardware such as a video camera, the other components of the device 40 may be implemented either partially or entirely in software which is stored in a memory and executed by one or more processors. These processors may include, for example, microprocessors, microcontrollers, DSPs, ASICs, PLDs (Programmable Logic Devices), FPGAs (Field Programmable Gate Arrays), other processing devices, and combinations thereof.

Those skilled in the art will be generally familiar with the components of the device 40, although the down-sampler 43, the interleaving system 46, and some aspects of the operation of the device 40 in accordance with embodiments of the invention are new, as will become apparent from the following detailed description. The specific type of each component will be implementation-dependent. The particular structure and operation of the encoder 44 may be different for different formats of video information, and the channel encoder 48, the modulator 50, and the transmitter 52 will similarly be dependent upon communication protocols and media using which information is to be transmitted.

Also, the present invention is in no way restricted to implementation in communication devices or other types of device having the specific structure shown in FIG. 3. Further or fewer components, with different interconnections, may be provided in a device in which embodiments of the invention are implemented.

In the device 40, video information is collected by the input video source 42, processed by the components 43, 44, 46,48, 50, and transmitted through the transmitter 52 to a destination, such as a video screen or a remote control center, the mobile server 24 of FIG. 1 for instance. In the transmit chain explicitly shown in FIG. 3, an interleaving system 46 is used to interleave collected information.

FIG. 4 is a block diagram of a communication device incorporating a de-interleaving system according to an embodiment of the invention, and represents a receive chain corresponding to the transmit chain of the device 40 as shown in FIG. 3.

The communication device 60, as shown, includes a receive chain in which a receiver 62, a demodulator 64, a channel decoder 66, a de-interleaving system 68, a video decoder 70, an up-sampler 71, and a video output device 72. These components, like those of the device 40 (FIG. 3), may be implemented in hardware, software, or some combination thereof.

In the receive chain of the device 60, video information received by the receiver 62 is processed by the demodulator 64 and the channel decoder 66. The de-interleaving system 68 is employed to reverse the interleaving, which may be bit/byte/packet interleaving for example, applied to the received video information by an interleaving system 46 at a transmitting device. De-interleaved video information is decoded by the video decoder 70, an MPEG4 decoder for instance, processed by the up-sampler 71 as described in further detail below, and output the video output device 72, which may be a display screen, for example.

In one embodiment, the transmit and receive chains shown in FIGS. 3 and 4 are provided in different devices. With reference to FIG. 1, the terminals 26, 28, 32, 34 may collect video information for transmission to the servers 24, 30 through a transmit chain as shown in FIG. 3. The servers 24, 30 incorporate a receive chain of FIG. 4 for processing video signals received from the terminals 26, 28, 32, 34. Additional functions may also be performed by transmitting and receiving devices. The servers 24, 30, for example, may also store and/or retransmit received video signals to the gateway 18 in their received or processed forms.

According to another embodiment, a single communication device incorporates both a transmit chain and a receive chain to enable both transmission and reception of information. In this case, a transmitter and a receiver may be implemented as a single component, generally referred to as a transceiver. Other components, or certain elements thereof, may similarly be used in both a transmit chain and a receive chain.

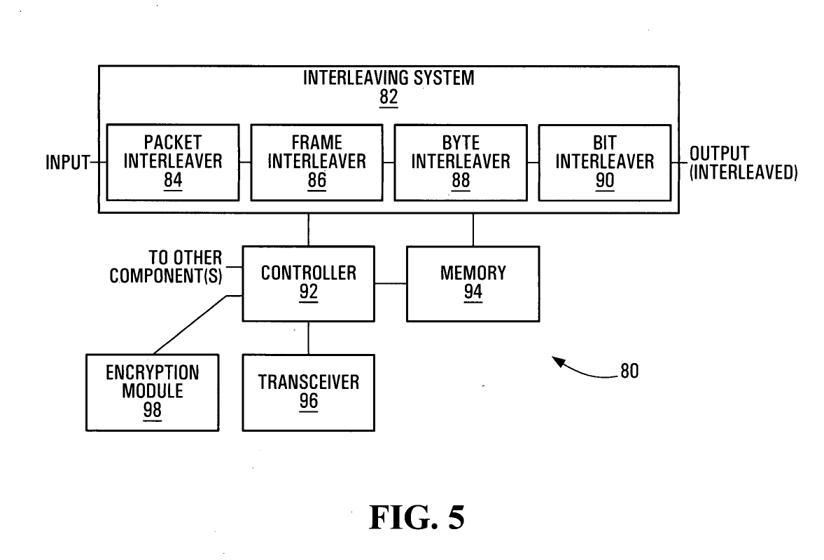

Turning now to the interleaving system 46 of FIG. 3, FIG. 5 is a block diagram of an illustrative example interleaving system. The interleaving system 82 of FIG. 5 implements an interleaving path which includes multiple interleavers 84, 86, 88, 90, each having a respective interleaving length. These interleavers include a packet interleaver 84, a frame interleaver 86, a byte interleaver 88, and a bit interleaver 90, although other types and lengths of interleavers may also or instead be provided in an interleaving system. In one embodiment, the interleaving lengths of interleavers in an interleaving system follow a discrete Fractal distribution.

Each interleaver in the interleaving system 82 interleaves input information according to its respective interleaving length, and together, the interleavers form an interleaving path which provides an overall or aggregate interleaving length.

An interleaver receives information, illustratively symbols from a fixed alphabet, as its input and produces the identical information, symbols in this example, at its output in a different temporal order. Interleavers may be implemented in hardware, or partially or substantially in software.

Used in conjunction with error correcting codes, interleaving may counteract the effect of communication errors such as burst errors. As will be apparent, interleaving is a process performed by an interleaver. Namely, interleaving is a digital signal processing technique used in a variety of communication systems. In one embodiment, this interleaving is implemented with FEC (Forward Error Correction) that employs error-correcting codes to combat bit errors by adding redundancy to information packets before they are transmitted. At the higher layer, an error recovery algorithm is matched with a particular FEC and interleave pattern. Because interleaving disperses sequences of bits in a bit stream so as to minimize the effect of burst errors introduced in transmission, interleaving can improve the performance of FEC and error recovery, and thus increase tolerance to transmission errors.

Other components may also be provided in an implementation 80 of the interleaving system 82, including a controller 92 to control which interleavers are active in the interleaving path and thus the aggregate interleaving length at any time, a memory 94 for storing information during interleaving and mappings between information types, operating conditions, and interleaving lengths, for example, a transceiver 96 for receiving and transmitting interleaving control information such as error information, communication link information, etc., and an encryption module 98, described in further detail below. The transceiver 96 may be a transceiver which is also used for transmitting and/or receiving information, or a different transceiver.

The controller 92 represents a hardware, software, or combined hardware/software component which controls which particular ones of the interleavers 84, 86, 88, 90 are active at any time in the interleaving path of the interleaving system 82. Interleavers may be enabled/activated or disabled/deactivated to provide a desired aggregate interleaving length on the interleaving path.

Various techniques may be used by the controller 92 to enable and disable interleavers in the interleaving system 82. In hardware-based embodiments, hardware chip select or analogous inputs may be used to enable an interleaver. Function calls represent one possible means of enabling software-based interleavers. Other techniques for enabling and disabling interleavers, which will generally be dependent upon the type of implementation of the interleavers, may be used in addition to or instead of the examples noted above.

The controller 92 may control the interleaving system 82 on the basis of control information received through the transceiver 96. Received control information may include, for example, monitored communication link information for a communication link over which interleaved information is to be transmitted and/or a command to activate one or more interleavers having particular associated interleaving lengths. Control information may also be transmitted to a remote interleaving system through the transceiver 96 to be used by that system in setting its aggregate interleaving length.

A type of information to be interleaved may also or instead determine an aggregate interleaving length to be used. For example, the controller 92 may enable and disable appropriate interleavers in the interleaving system 82 to provide a first aggregate interleaving length where the information comprises still images and a second aggregate interleaving length shorter than the first interleaving length where the information comprises video.

Mappings between the above and/or other conditions and corresponding interleaving lengths may be pre-stored in the memory 94 for access by the controller 92. The controller may also or instead store new mappings to the memory 94 as new conditions and suitable aggregate interleaving lengths are determined.

The system of FIG. 5 may use two kinds of classical interleavers, which are block and convolutional interleavers. In a block interleaver, input information is written along the rows of a matrix in the memory 94, and then read out along the columns. Therefore, in a wireless Video over IP network, an interleaver may be installed in end point (or mobile terminal) devices and then each end point device executes interleaving when a video packet is transmitted.

The major difference between a block interleaver and a convolutional interleaver is that a convolutional interleaver treats Protocol Data Units (PDUs) continuously, while a block interleaver splits a continuous PDU stream into blocks and then scrambles each block independently.

By definition, convolution is a mathematical operation that is carried out in the time domain whose frequency domain equivalent is multiplication. A finite field multiplication in the frequency domain can span into an infinite field in the time domain, and as such, the convolutional interleaver can stretch from the past to the future dependently. In FIG. 5, each interleaver can be implemented as either a block or convolutional interleaver. For example, the packet and frame interleavers 84, 86 may be implemented as block interleavers, while the byte and bit interleavers 88, 90 are implemented as convolutional interleavers. Any other combination, in which only one or different types of interleavers are implemented, is also possible. Different combinations may have different error correction performance pertaining to different channel models, such as Rayleigh or Rician models, etc., and accordingly error correction performance may be one criterion used to select the particular type of interleaver used in an implementation.

There are two fundamental reasons for using a multi-layer interleaving system such as 82. The first is that a recent study shows that the error and loss pattern follow a so-called self-similar structure [Huang]. This means the burst error can accrue on any scale, from the bit level all the way to the packet level, or even session level.

The second reason is that even if there is no error, encryption may be desirable when the original signal goes through wireless or Internet paths, to prevent access to transmissions by an eavesdropper or hacker. Dedicated encryption costs extra power and complexity. Combining the functions of encryption and interleaving can simplify the overall design, and reduce the cost, physical size, and power consumption.

An interleaver according to another aspect of the invention prevents unauthorized access of data by combining interleaving with encryption. In one embodiment, a DES [Preissig] or DES-like algorithm is used in combination with an interleaver.

This combination is represented in FIG. 5 by the encryption module 98, through which the controller 92, or more generally the interleaving system 82, receives security information such as an encryption key. This key may be entered manually by an operator or user, or may instead be stored at a communication device. In one embodiment, the length of the encryption key is configurable upon request of the user.

The idea of encrypting information directly with interleaving, instead of in a stand-alone encryptor, represents brand new thinking for lightweight flexible design. The key may be used to encrypt the information itself, or to determine the position of original information after interleaving, rather than the encrypting the actual information. The latter provides encryption which is a magnitude of about N!/2\hat{ }N, where N is the length of the key, stronger than the former.

Encryption can be done multi-dimensionally using the interleaving system 82, with more than one interleaver handling encryption using sections of a single key, for example.

Security information, a key for instance, can be a combination of numerical number and alphabetical character. For a simple implementation, we can pick a number from a password, if the password is “1326” and the frame interleaver 86 is used for combined interleaving and encryption, the first frame is swapped with the third frame in position, the second and the sixth frames are swapped, and so on. For MPEG frames which are sent by group, for example, the group leader is called the I frame, and contains a complete image. The I frame is followed by a number of P frames, with each P frame containing only the frame to frame differences not the complete image. When the number of frames in a group is less than 10, security information could be interpreted one digit at a time, as above. If the number of frames in a group is between 10 and 100, then the security information could be interpreted differently, two digits at a time for example, and when the group number is between 100 and 1000, security information might be interpreted three digits at a time, and so on. For instance, when the group number is 60, a key of “1646” may cause the 16^{th} frame to be swapped with the 46^{th} frame during interleaving. These rules could be predetermined, or exchanged along with keys using standard secured key exchange protocols or using some other transfer mechanism.

In one embodiment, simple interleaving is operating in the end point device of a Video over IP network with legacy wireless systems. For an interleaver having a buffer of size M, a video packet to be transmitted is written to the buffer along the rows of a memory configured as a matrix of size k, and is then reads out along the columns. On the receive side, a de-interleaver writes and reads this transmitted video packet in the opposite direction. The de-interleaved video packet is then forwarded with FEC to other receiver components such as a video decoder.

Multi-dimensional interleave may operate in a very similar fashion, except that each level of interleaving is executed on different layers. Although a header for each layer might not be interleaved, the payload preferably is. For an MPEG4 packet transmitted from a terminal to a server and forwarded to a gateway as described above with reference to FIG. 1, the packet header may include an MPEG4 header, an Ethernet header, an IP header, a UDP (User Datagram Protocol) header, an RTP (Real-time Transport Protocol) header, an RTSP (Real-Time Streaming Protocol) header, a FEC field and an encrypted and interleaved payload field.

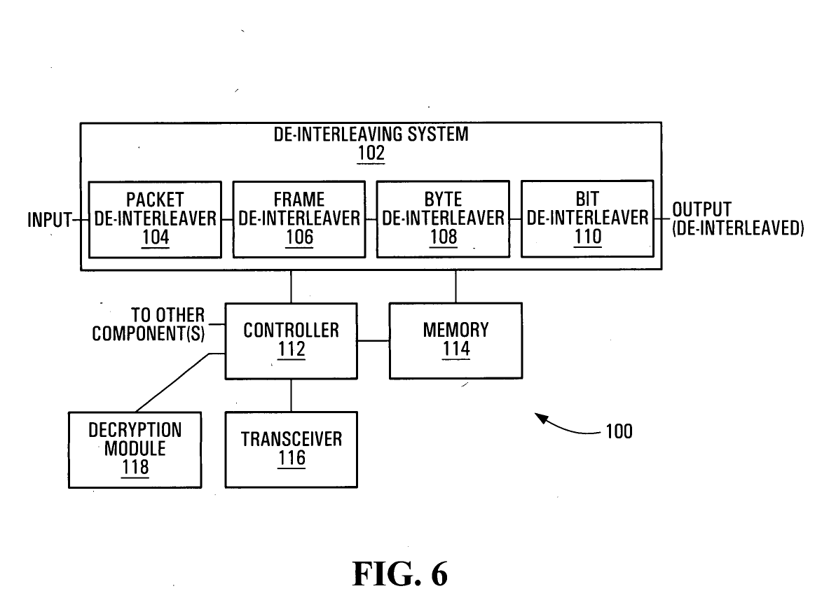

FIG. 6 is a block diagram of an illustrative example de interleaving system of an embodiment of the invention. The system 100 includes an interleaving system 102 having packet, frame, byte, and bit de-interleavers 104, 106, 108, 110, a controller 112, a memory 114, a transceiver 116, and a decryption module 118. The system 100 performs inverse processing to the interleaving system of FIG. 5, and accordingly its operation will be apparent from the foregoing.

A special algorithm is used to manage the interleaver size according to embodiments of the invention. During transmitting of a video packet, the situation of wireless network is reported. Video packets transmitted in a wireless network may make the devices of the wireless network such as gateways, routers, and media gateway controllers very busy. In this case, burst error may occur due to packet loss caused by network congestion or interference on the wireless path. Therefore, control of this burst error, through adaptive interleaving as disclosed herein, may be particularly useful.

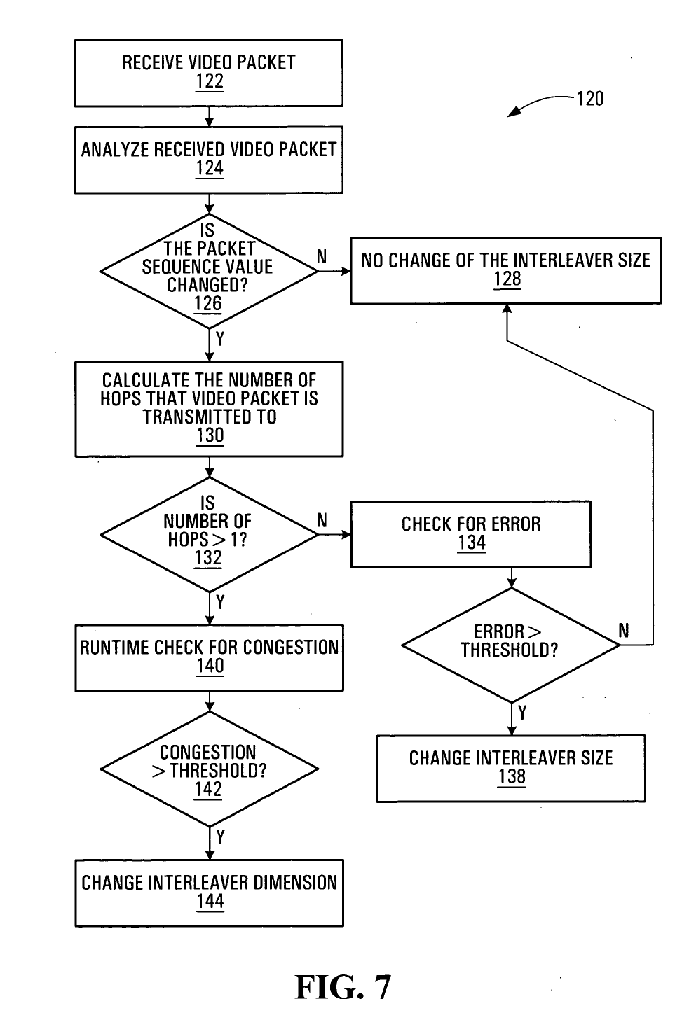

FIG. 7 shows a burst error reduction algorithm with adaptive control. It changes size and/or dimension of interleavers in an interleaving system according to information provided by a run-time algorithm.

The method 120 of FIG. 7 will be described in detail with reference to MPEG4 as an illustrative example video information format. Referring again to FIG. 2, the typical MPEG4 file format and streaming format are shown. Metadata in the file known as “hint tracks” provides instructions, telling a server application how to deliver the media data over a particular delivery protocol. There can be multiple hint tracks for one presentation, describing how to deliver over various delivery protocols. The diagram shows the container relationship with RTP protocol hint tracks to stream a simple video movie.

To stream multiple movies, the higher layer protocol such as RTSP will interleave the lower layer RTP streams into one aggregated stream, as shown in FIG. 4, where each channel ID corresponds to one movie.

Each sender and receiver receives video packets from each other at 122. Each of the receiver and sender analyzes the received video packet at 124, and in particular video packet headers according to one embodiment, determines at 126 whether the sequence number of RTSP is changed, and if the sequence number is changed, then the number of hops that the video packet passed is calculated at 130. If the sequence number is not changed, then a current interleaving size is not changed, as indicated at 128.

After calculating the number of hops at 130, and also the number of errors reported on different layers at 134 if the number of hops is greater than one (132), a determination is made at 136 as to whether the overall error is above a threshold, which may be predetermined and stored at a device, determined by an interleaving system or other component of a device, or specified in control information received by a device for instance. If so, then interleaver size and thus interleaving length for an interleaving path is adjusted at 138. This may involve selecting a different interleaver, for example.

At 140, if the number of hops for a packet is greater than 1, as determined at 132, a runtime check for congestion on a communication link is performed at 140. Illustrative examples of runtime checks are described in further detail below. If congestion is above a predetermined, selected, or remotely specified threshold, as determined at 142, then interleaver dimension is changed, at 144, by enabling one or more additional interleavers or disabling one or more currently active interleavers.

Modifications to interleaving size and/or dimension are applied to subsequent video packets. This method 120 has an advantage that it is adaptable to various communication environments. To ensure continuous operation, a mode ID or other control information can be transmitted at the beginning of each packet so that a receiver adapts accordingly with the transmitter. For example, a mode ID might map to preset interleaver dimension and size. In one possible mapping, a mode 0 maps to one dimension/size one, which means no interleaving is applied, such as for default or initialization communication usage. Mode 1 might then be mapped to two dimensions/size (256 bytes, 8 bits), mode 2 may indicate two dimensions/size (1024 bytes, 8 bits), etc. These mappings may be stored in a memory such as the memories 94, 114 (FIGS. 5, 6) for use during interleaving and de-interleaving operations.

Interleaver parameter changes may be terminal-driven in some embodiments. In the system of FIG. 1, for example, when communication channel conditions between the mobile server 24 and the terminals 26, 28 deteriorate, terminal demand for stronger interleaving may escalate, and the mobile server 24 may grant a request from a terminal based on combination of a Fractal random model and an empirical history bar graph collected in a database, for example.

In a typical multimedia communication system, a session consists of a number of packets, a packet consists of a number of frames, a frame consists a number of bytes, a byte consists a number of bits. In a seldom-happening worst case, all four levels of interleaving as shown in FIG. 5 can be used, i.e., to swap packet, on top of swap frame, (in turn) on top of swap byte, (and again) on top of swap bit. A bit interleaver with size of 4 bits, operates 4 bits by 4 bits. So on and so forth for byte, frame, packet interleavers.

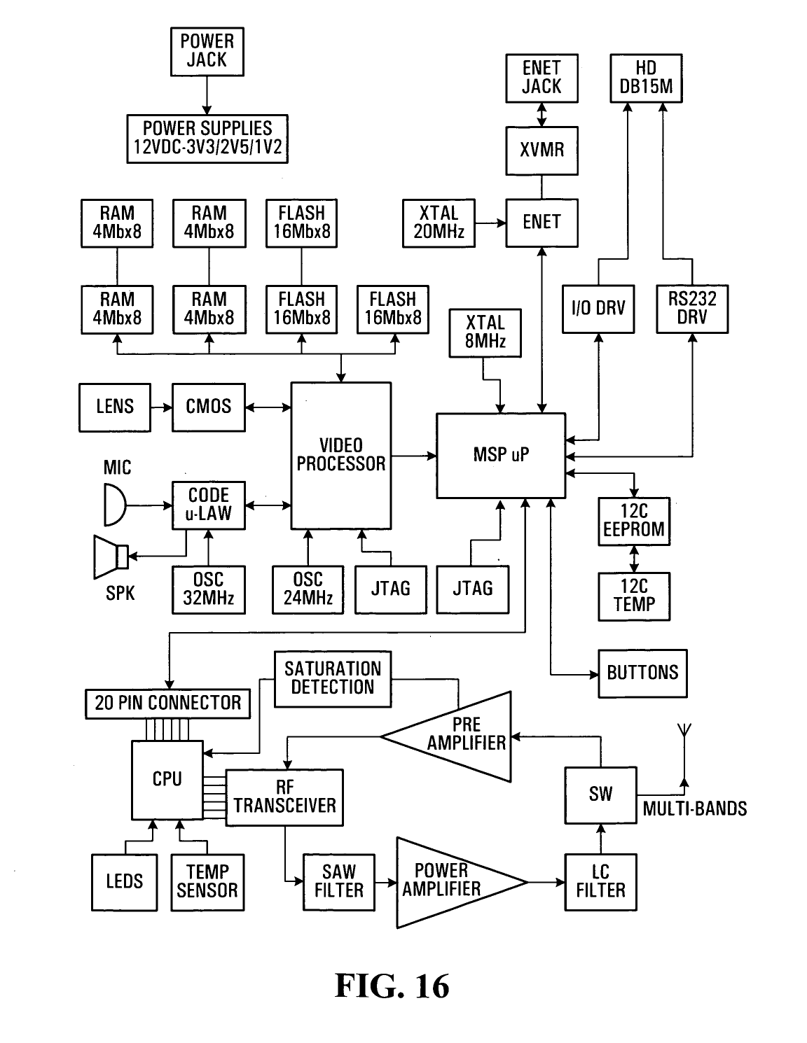

A mode ID or other control information may be either exchanged at the beginning of communication using a modified SDP (Session Description Protocol), or constantly enforced by each packet header and processed by a communication processor, such as the MSP microprocessor shown in FIG. 16.

According to one embodiment, the mode ID is called a header-tail marker, and it contains packet length information as well. At the receiving end, the ID is verified, illustratively by counting number of bytes in a packet, and corrected if necessary, at a channel decoder before the de-interleaving starts. This way, an error correction decoder such as a Reed Solomon channel decoder will be maximized at its error correction capability. In a traditional error correction system, if one byte is lost, the whole block of the code is shifted, and the Reed Solomon code will think every byte is in error, and halt the decoding process. However, with a multi-dimensional interleaver as disclosed herein, a missing byte can be identified using a header-tail marker and remaining bytes can be shifted accordingly, which effectively improves the error decoding performance.

The foregoing description relates primarily to interleaving and de-interleaving in the devices 40 (FIG. 3) and 60 (FIG. 4). Another aspect of the present invention relates to down-sampling and up-sampling functions, which in the devices 40 and 60 are performed by the down-sampler 43 and the up-sampler 71, respectively.

To compress real time live MPEG streaming video and simplify processing of MPEG information, down-sampling is traditionally performed either in the time domain or in the space domain. By definition, down-sampling in the context of video/image information means skipping pixels in an original image in a certain way. One simple down-sampling scheme involves skipping every second pixel. In an embodiment of the present invention, the compressed data rate is made extremely low, such as 9600 bits per second, by using a combination of both time and space domain down-sampling in the down-sampler 43. In order to recover such overly down-sampled information, a new up-sampling technique is proposed for the up-sampler 71 at a receiver to maintain real time picture quality.

Thus, according to another aspect of the invention, a Fractal structured error concealment algorithm for an up-sampler is proposed, where a smoothing factor is proportional to the size of expected error, following a Fractal distribution.

An MPEG coded bit stream is very sensitive to channel disturbance due to MPEG VLC (Variable Length Coding). A single bit error can lead to very severe degradation in a part of, or entire slice of, an image. This is of particular concern if the physical transmission medium has limited bandwidth and high error rate, such as in the case of a wireless communication link.

MPEG4 has a built-in packetization technique wherein several macroblocks (a 16×16 pixel block) are grouped together such that there is no data dependency on the previous packet. This helps in localizing errors. Numerous schemes have been proposed to combat data loss in video decoding. Some use DCT (Direct Cosine Transform) or MAP (Maximum A Posteriori) estimation. These algorithms are either computationally intensive or lead to block artefacts. In one embodiment of the invention, a simple interpolation with a Fractal-weighted smoothing factor is proposed.

A spatial error concealment scheme may be used, for example, for a frame, where no motion information exists. It makes use of the spatial similarity in a picture. Most smoothing horizontal and vertical algorithms use the linear interpolation. In contrast, it is proposed that the weight be set according to a Fractal distribution, as the error correlation factor tends to be Fractal distributed.

Temporal error concealment is a technique by which errors in P pictures (predictive coded using the previous frame) are concealed. For the similar reason as in the spatial case, the following interpolation is proposed:
V(x,y)=alpha(i)*V(x−i,y)+alpha(i)*V(x+i,y),
where V(x,y) is the motion vector at the location of (x,y), alpha(i) is the smoothing factor, and “i” is the distance between damaged to undamaged block. Alpha(i) preferably follows the Fractal distribution, with the value of the Fractal index depending on the type of movie or amount of motion present. In one embodiment, a Fractal index table is stored in memory and accessed to determine the smoothing factor. Such a table might store two values, one for a movie or video having a low amount of motion, and another for a fast-motion “action” movie or video. An index table may store more than two values, and other techniques may be used to calculate or otherwise determine smoothing factors instead of accessing predetermined factors stored in a memory.

An up-sampler and up-sampling method according to embodiments of the present invention may thereby interpolate damaged blocks of information. It should be appreciated that a “damaged” block may include a block, illustratively a pixel, which was skipped during down-sampling, or a block which was actually damaged or lost during transmission. References herein to damaged blocks should thus be interpreted accordingly.

The description above discloses interleaving and error concealment aspects of the present invention. The next section elaborates on a special way to report any issues raised by a soft decoder and player, and how to determine when to switch the interleaver size/dimension.

In one possible implementation, the advantages of client server architecture are exploited, such that a server hosts highly sophisticated centralized run-time calculations and even prediction. This optimizes a trade-off between expected flexibility of a soft radio and harsh portable performance required by applications such as transmitting real time video.

Hardware-based interference detection and error counting may also be implemented to provide accurate up-to-the-minute reflection of real time first hand measurements, such that closed loop performance can be achieved.

By distributing functions between a sensor terminal and a server, a balance of flexibility and reliability is achieved for a new distributed software radio architecture.

In addition, by introducing network layer coordination, the interference caused by irregular noise sources can be partially mitigated to maximize video quality “on the fly”.

Runtime techniques are also proposed to facilitate implementation of embodiments of the invention with wireless video products.

In one embodiment, a number of remote handheld cameras are connected back to a control/call center, such as a PC or Workstation. In FIG. 1, this is represented by the terminals and servers. The amount of available processing power tends to be limited in the remote side, but not in fixed or mobile control center side, where wired power supply or wet battery from service truck, for example, is expected.

As a consequence, the control center can perform measurements and/or calculations and find out the optimized operating characteristics for both remote and central units.

When the environment changes, the system is able to train itself, and to adapt to fit. The detection of impairment relies largely on runtime software, and the simple multi-layer configurable circuits in the remote.

Most (if not all) error control methods used in the past, like Turbo codes for channel coding or concealment for source coding, react on error. However, embodiments of the invention go a step further. Instead of simply reacting on a source error, measuring, classifying and actively predicting provides for avoiding major potential errors. Keeping a history in a database also provides for off-line analysis. Where the control center has enough processing power, an advantage of this new centralized software control improves overall performance.

As mentioned above, software defined radios are gaining attention, especially in military and public safety application arenas. Nevertheless, the key issue of software radio is the reliability and robustness. Software tends to have more non-repeatable runtime bugs compared with hardware, and as a consequence, the study towards run-time debug and reverse engineering to report online problems becomes very important.

Many strategies aimed to reverse-engineer dynamic models, and in particular interaction diagrams (diagrams that show objects and the messages they exchange), are reported in the literature. Differences are summarized in Table 1 below. Although not exhaustive, this table does illustrate the differences relevant to aspects of the present invention.

TABLE 1

| | Jerding | Walker | Systa | Kollmann | Richner |
|---|---|---|---|---|---|
| Class/Object | Class | Class | Class | Object | Object(memory |
| level | | | | | address) |
| Information | Source code | Virtual Machine | Customized | N/A | Source code |
| source | instrumentation | | Debugger | | instrumentation |
| Language | C++ | Smalltalk | Java | Java | Smalltalk |
| Control flow | No | No | Yes | No | No |
| Conditions | No | No | No | No | No |
| Patterns | String matching | No | String matching | N/A | Provided by the |
| | (heuristic) | | | | user |
| Model | MSC | Custom diagram | SD (based on the | UML CD | UML SD |
| produced | | | UML notation) | | |

The strategies reported in Table 1 [Jerding, Walker, Systa, Kollmann, Richner] are compared according to seven criteria:
Whether the granularity of the analysis is at the class or object level. In the former case, it is not possible to distinguish the (possibly different) behaviours of different objects of the same class, i.e., in the generated diagram(s), class X is the source of all the calls performed by all the instances of X.
The information source. In [Richner], the memory addresses of objects are retrieved to uniquely identify them, though (symbolic) names are usually used in interaction diagrams. Although this issue is not discussed by the authors, the reason is likely that retrieving memory addresses at runtime is simpler than using attribute names and/or formal parameter and local variable names to determine (symbolic) names that could be used as unique object identifiers. This requires more complex source code analysis (e.g., problems due to aliasing). Last, it seems that, in [Richner], methods that appear in an execution trace are not identified by their signature, but by their name (parameters are omitted), thus making it difficult to differentiate calls to overloaded methods.
Source code analysis. This is not explicitly mentioned in [Kollmann]. In the simple example they use, interacting objects can easily be identified as they correspond to attributes and there is no aliasing.
The strategy used to retrieve dynamic information (source code instrumentation, instrumentation of a virtual machine, or the use of a customized debugger) and the target language.
Whether the information used to build interaction diagrams contains data about the flow of control in methods, and whether the conditions corresponding to the flow of controls actually executed are reported. Note that in [Systa], as mentioned by the authors, it is not possible to retrieve the conditions corresponding to the flow of control since they use a debugger. The information provided is simply the line number of control statements.
The technique used to identify patterns of execution, i.e., sequences of method calls that repeat in an execution trace. The authors in [Jerding, Richner, Systa] aim to detect patterns of executions resulting from loops in the source code. However, it is not clear, due to lack of reported technical details and case studies, whether patterns of execution that are detected by these techniques can distinguish the execution of loops from incidental executions of identical sequences in different contexts. This is especially true when the granularity of the analysis is at the class level. For instance, it is unclear what patterns existing techniques can detect when two identical sequences of calls in a trace come from two different methods of the same class (no loop is involved).
The model produced: Message Sequence Chart (MSC), Sequence Diagrams (SD), Collaboration Diagram (CD). Note that in [Kollmann], since the control flow information is not retrieved, the sequences of messages that appear in the generated collaboration diagram can be incorrect, or even unfeasible. Also, since the strategy only uses the source code, the actual (dynamic) type of objects on which calls are performed, which may be different from the static one (due to polymorphism and dynamic binding), is not known. Note that such a static approach, though producing UML (Unified Modeling Language) [Booch] sequence diagrams with information on the control flow, is also proposed by tools such as Together [Kern].

This suggests that a complete strategy for the reverse engineering of interaction diagrams (e.g., a UML sequence diagram) should provide information on: (1) The objects (and not only the classes) that interact, provided that it is possible to uniquely identify them; (2) The messages these objects exchange, the corresponding calls being identified by method signatures; (3) The control flow involved in the interactions (branches, loops), as well as the corresponding conditions. None of the approaches in Table 1 cover all three items and this is one goal of some embodiments of the invention.

Another issue, which is more methodological in nature, is how to precisely express the mapping between traces and the target model. Many of the papers published to date do not precisely report on such mapping so that it can be easily verified and built upon. One exception is [Kollmann], but this approach is not based on execution traces, as discussed above. A strategy according to one embodiment of the invention is to define this mapping in a formal and verifiable form as consistency rules between a metamodel of traces and a metamodel of scenario diagrams, so as to ensure the completeness of metamodels and allow their verification.

According to an embodiment of the invention, special run-time algorithm is used to detect the errors on each layer of a software radio. Errors can happen in any layer, caused by its next low layer or high layer. An error happening in any layer can cause the final freeze of streaming video image through a wireless link or some other failure. The techniques described herein allow effective reporting of runtime problems, such that a control center can identify the problem, carry out analysis and take final actions, according to a learned or preset database.

One objective of this approach is to define and assess a method to reverse engineer UML sequence diagrams from execution traces, compare with an expected one, and report any discrepancy. Formal transformation rules may be used to reverse engineer diagrams that show all relevant technical information, including conditions, iterations of messages, and specific object identities and types involved in the interactions.

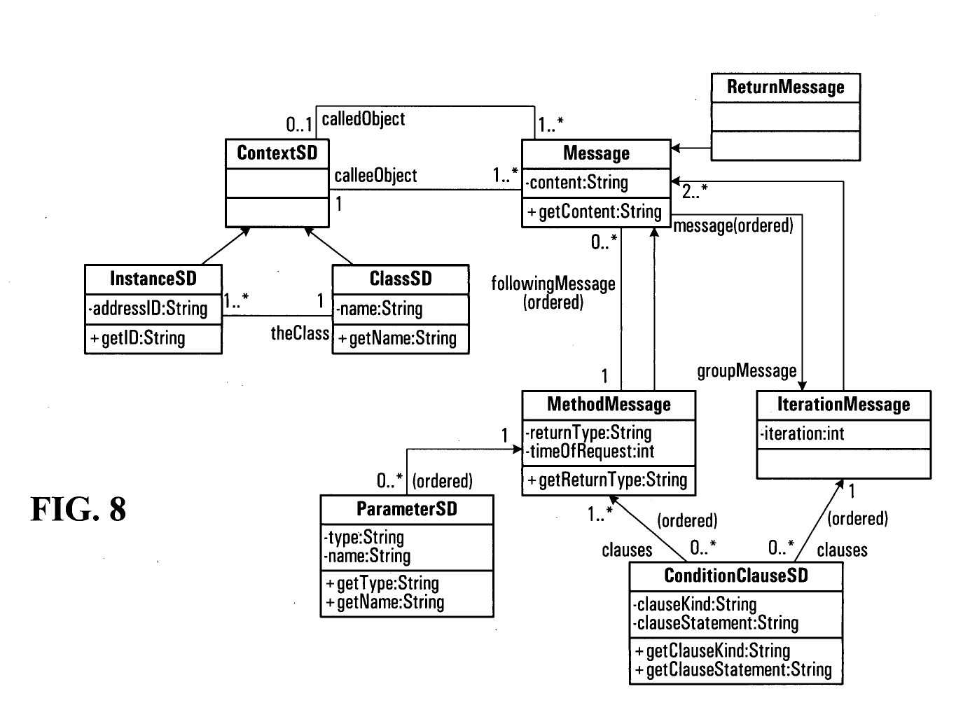

A high-level strategy for the reverse engineering of sequence diagrams involves incrementing the source code, executing the instrumented source code (thus producing traces), and analyzing the traces in order to identify repetitions of calls that correspond to loops. An example metamodel of scenario diagrams that is an adaptation of the UML meta-model for sequence diagrams is shown in FIG. 8.

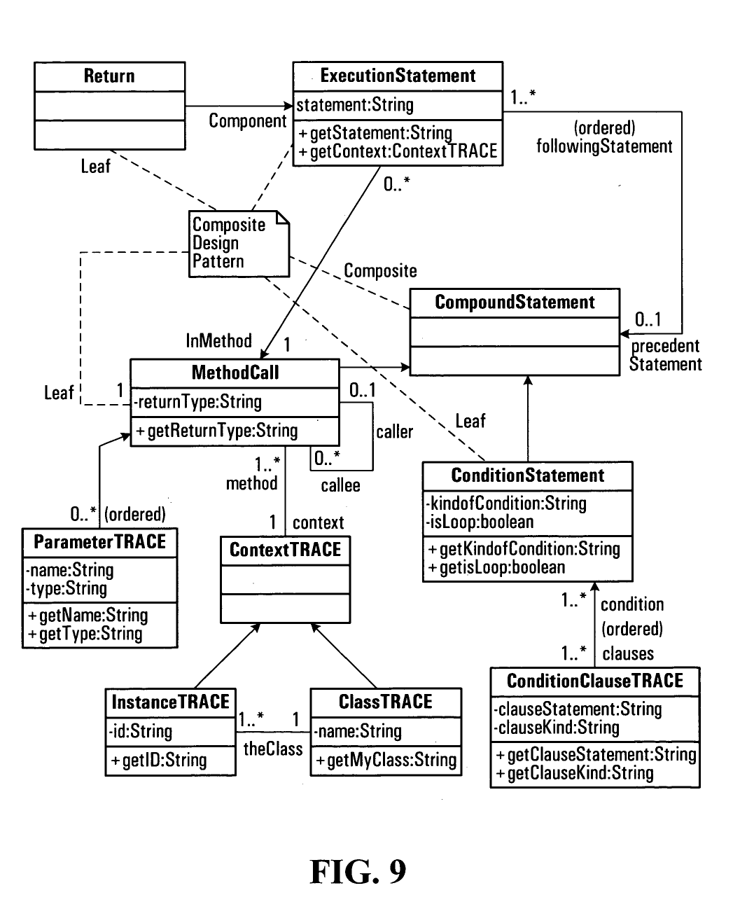

This helps define the requirements in terms of information needed to retrieve from the traces, i.e., what kind of instrumentation is needed. In turn, this results in a metamodel of traces (FIG. 9).

Then, the execution of the instrumented system produces a trace, which is transformed into an instance of the trace metamodel, using algorithms which are directly derived from consistency rules (or constraints) defined between the two metamodels. Those consistency rules are described in OCL (Object Constraint Language) and are useful in several ways: (1) They provide a specification and guidance for transformation algorithms that derive a scenario diagram from a trace (both being instances of their respective meta-model), (2) They help ensure that meta-models are correct and complete, as the OCL expression composing the rules is based on the meta-models. The implementation of a prototype tool uses Perl for the automatic instrumentation of the source code and Java™ for the transformation of traces into scenario diagrams. The target language may be C++, for example, but it can be easily extended to other similar languages such as Java, as the executed statements monitored by the instrumentation are not specific to C++ (e.g., method's entry and exit, control flow structures). Reporting of errors or interfaces may be accomplished, for example, with existing UML CASE tool for further analysis.

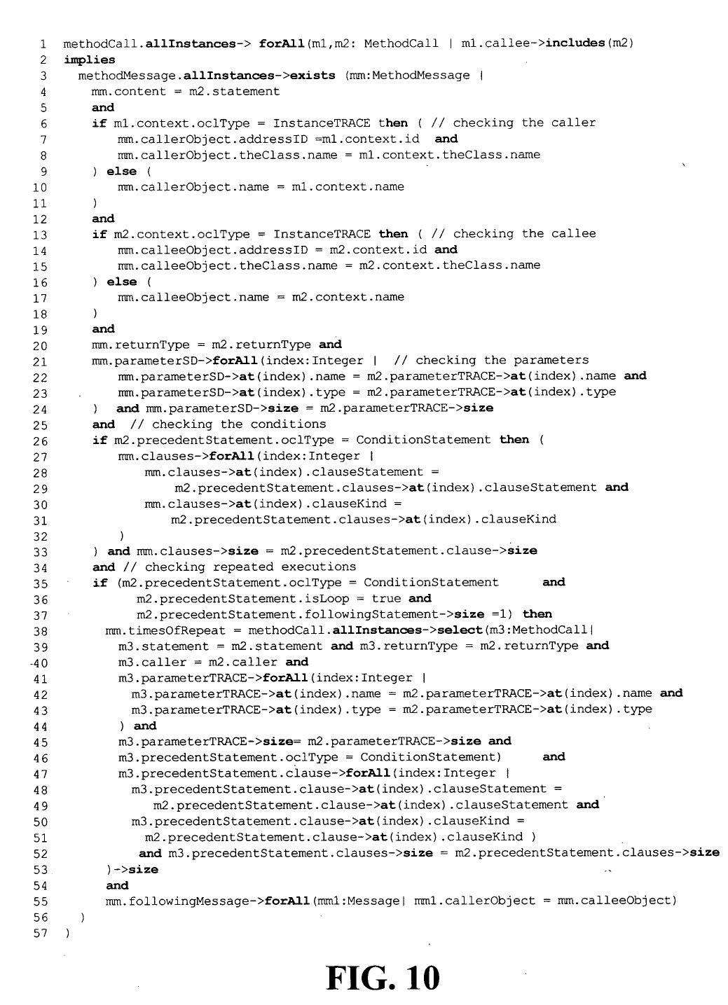

Sequence diagram [Booch] is one the main diagrams used during the analysis and design of object-oriented systems, since a sequence diagram is usually associated to each use case of a system. A sequence diagram describes how objects interact with each other through message sending, and how those messages are sent, possibly under certain conditions, in sequence. In one embodiment, the UML metamodel, that is, the class diagram that describes the structure of sequence diagrams, is adapted so as to ease the generation of sequence diagrams from traces. An example of sequence diagram metamodel code is shown in FIG. 10.

Messages (abstract class Message) have a source and a target (callerObject and calleeObject respectively), both of type ContextSD, and can be of three different kinds, including a method call (class MethodMessage), a return message (class ReturnMessage), or the iteration of one or several messages (class IterationMessage). The source and target objects of a message can be named objects (class InstanceSD) or anonymous objects (class ClassSD).

Messages can have parameters (class ParameterSD) and can be triggered under certain conditions (class ConditionClauseSD): attributes clauseKind and clauseStatement indicate the type of the condition (e.g., “if”, “while”) and the exact condition, respectively. The ordered list of ConditionClauseSD objects for a MethodMessage object corresponds to a logical conjunction of conditions, corresponding to the overall condition under which the message is sent. The iteration of a single message is modeled by attribute timesOfRepeat in class MethodMessage, whereas the repetition of at least two messages is modeled by class IterationMessage. This is due to the different representation of these two situations in UML sequence diagrams. Last, a message can trigger other messages (association between classes MethodMessage and Message).

Source code is instrumented by processing the source code and adding specific statements to retrieve the required information at runtime. These statements are automatically added to the source code and produce one text line in the trace file, reporting on:
Method entry and exit. The method signature, the class of the target object (i.e., the object executing the method), and the memory address of this object are retrieved.
Conditions. For each condition statement, the kind of the statement (e.g., “if”) and the condition as it appears in the source code are retrieved.
Loops. For each loop statement, the kind of the loop (e.g., “while”), the corresponding condition as it appears in the source code, and the end of the loop are retrieved.

These instrumentations are sufficient, as it is then possible to retrieve: (1) The source of a call (the object and method) in addition to its target, as the source of a call is the previous call in the trace file; and (2) The complete condition under which a call is performed (e.g., due to nested if-then-else structures). The conjunctions of all the conditions that appear before a call in the trace file form the condition of the call.

When reading trace files produced by these additional statements, it is possible to instantiate the class diagram in FIG. 9, which is the metamodel for traces. This class diagram is similar to a sequence diagram metamodel, though there are some important differences. For instance, a MethodMessage object has direct access to its source and target objects (instances of ContextSD) whereas a MethodCall has access to the object that executes it only (i.e., the target of the corresponding message) and has to query the method that called it to identify the source of the corresponding message. As a consequence, the mapping between the two is not straightforward and the identification of a return message for a call, the complete conditions that trigger calls, and calls that are repeated and located in a loop, are pieces of information that do not appear as is in the trace file but must be computed.

Three consistency rules, illustratively expressed in OCL, have been defined to relate an instance of the trace metamodel to an instance of the sequence diagram metamodel. Note that these OCL rules only express constraints between the two metamodels. They provide a specification and insights into implementing such algorithms. These three rules identify instances of classes Methodmessage, ReturnMessage and IterationMessage (sequence diagram metamodel) from instances of classes MethodCall, Return, and ConditionStatement (trace metamodel), respectively. We only present the first one (from MethodCall to MethodMessage instances) in FIG. 10.

The first three lines in FIG. 10 indicate that if method m1 calls method m2 (instances of class MethodCall in the trace metamodel), then there exists a MethodMessage mm whose characteristics (attribute values and links to other objects) are described in the rest of the rule. The instance mm maps to the instance m2 (line 4). Then lines 6 to 11 check the link between mm and its callerObject (instance of class ContextSD), i.e., whether mm is linked to the object that performed the call to m2. Lines 13 to 18 check the link between mm and its calleeObject, i.e., the object that executed m2. Lines 20 to 24 check that the parameters of mm (instances of class ParameterSD) are consistent with the parameters of m2 (instances of ParameterTrace). Lines 26 to 33 check the conditions that may trigger mm and the order in which they are verified. Last, lines 35 to 53 determine how many times message mm has been sent.

In a software radio architecture according to an embodiment of the invention, the above method is used as follows. The decision related functions (such as when to switch operation mode) are performed at a server or control center site, whereas part of information collection (such as Error event, interference event and Bit Error Rate) resides on a mobile device. The other part of information collection (such as number of hops a packet goes through) resides on server itself. The runtime algorithm described above is implemented in the server, also referred to herein as a control center. The control center, or preferably control center software, configures and controls wireless devices, video encoder devices, and Internet packet forwarding devices, and constantly monitors itself against desired performance. In addition, less complicated more robust watch-dog software may be written in script language, for example, for the higher level gateway, and is used to further monitor the heart-beat of each control center, to make sure entire network is up and running around the clock.

Consider the following example scenario. During runtime, a mobile terminal which detects an interference event will report the event to the control center. A terminal might also or instead be capable of determining that an event is imminent or likely to occur, based on historical interference patterns for instance, and report this to the control center.

The control center will then look into its database for previous records, if the reported event has happened before, and fetch any previously used solution if it determined a solution or action to take responsive to the event in the past. The solution may be to simply double or otherwise adjust interleaver length.

If the event has never been reported before, the control center will call up a runtime method, such as the method of FIG. 7, to make a new decision. The runtime method will preferably also perform a follow up to check that the solution actually worked. If not, it may report to gateway server for further help. The gateway server may maintain a more extensive database, by backing up all control centers' databases, for both the mobile server 24 and the remote server 30 in FIG. 1 for instance. An operator may be alerted to handle the event manually, if all servers are not able to solve the problem automatically.

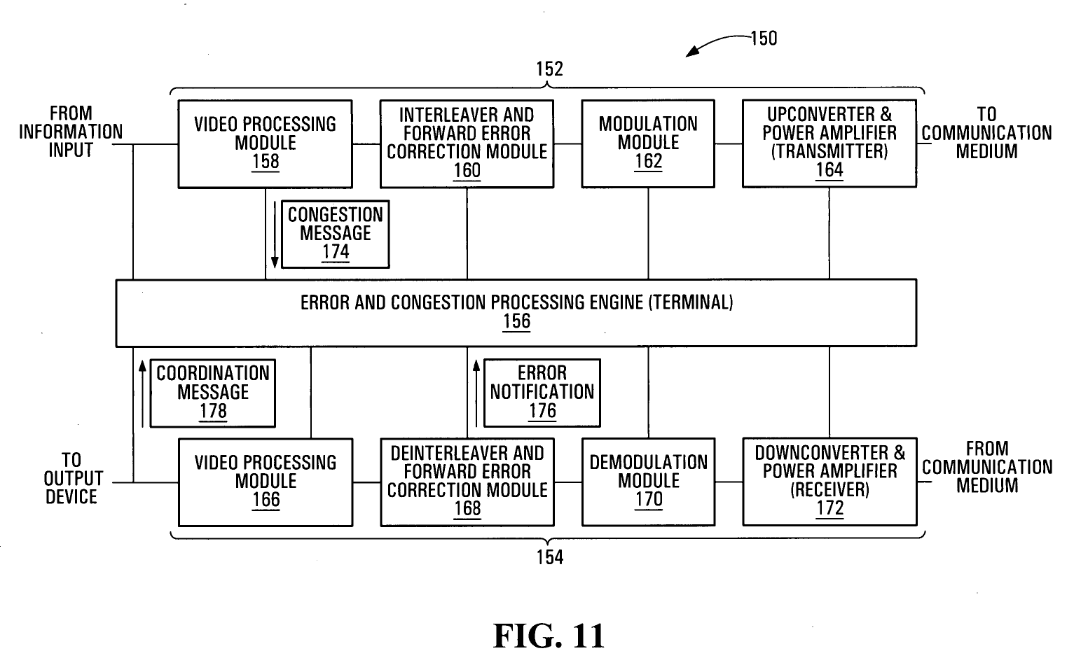

FIG. 11 depicts a conceptual block diagram for terminal incorporating several of the new features described above, in an illustrative example special “engine”. With reference to FIG. 1, mobile terminals 26, 28, remote terminals 32, 34, or both, may have a structure which is substantially similar to that of the terminal 150.

The terminal 150 includes a receive chain 152, a transmit chain 154, and a terminal portion 156 of an error and congestion processing engine. The structures of the receive and transmit chains 152, 154 are substantially similar to those shown in FIGS. 3 and 4. The receive chain 152 includes components 158, 160, 162, 164, and the transmit chain includes components 166, 168, 170, 172, the operation of which will be apparent from the foregoing description. The video processing modules 158, 166 may be implemented as a video card incorporating a video encoder/down-sampler and decoder/up-sampler as shown in FIGS. 3 and 4, for example, and the engine 156 is one possible implementation of the controllers 92, 112. The other components shown in FIG. 11 may similarly be reconciled with those in FIGS. 3 and 4.

Any or all of these components may interact with the engine 156. However, as described below, some embodiments of the invention involve interactions between the engine 156 and only some of these components, even though all components are shown in FIG. 11 as being interconnected with the engine 156.

According to one particular embodiment, the error and congestion processing engine 156 has 3 inputs and 4 outputs. The error notification 176 from the de-interleaver and forward error corrector 168 represents an input which indicates whether the terminal 150 is currently experiencing interference, the coordination message 178 represents an input of the bit error rate experienced, and the congestion message 174 represents a congestion indicator which indicates whether the terminal 150 is experiencing congestion for communications with a control center, for example.

Other inputs may also be provided, but have not been shown in FIG. 11 to avoid congestion. One or more components of the receive chain 154 may provide the engine 156 with inputs received as control traffic from a control center. Although not explicitly shown in FIG. 11, a user input device might also be provided for the terminal 150 through which a user can enter a key, password, or other security information for use in encrypting and/or decrypting information.

Outputs of the engine 156 may include, among others, outputs to the interleaver and forward error correction module 160 and the corresponding de-interleaver module 168 for controlling interleave dimension and size and outputs to the modulation module 162 and the upconverter and power amplifier 164 for controlling communication parameters, such as soft radio waveform and hopping pattern (frequency duration), respectively.

The engine 156 may also provide outputs to the transmit chain 152 for transmission to a control center. As shown, the engine 156 is connected to the transmit chain at an input to the video processing module 158, although transmit traffic insertion for the engine 156 may be provided at other points in the transmit chain, as outputs from the engine 156 might not require video processing.

The error and congestion processing engine 156 may be responsible for carrying out any or all of the following actions (either on-line or off-line) with the assistance of interconnected blocks in both transmitting data (plus control) paths and receiving data (plus control) paths represented by the transmit and receive chains 152, 154:
a. For passive on-line coordination, each terminal may be equipped with a special interference detector by measuring power amplifier distortion, or alternatively, if a soft decoding technique is used, this can be fulfilled by indicating that a maximum allowed number of iterations has been reached while convergence criteria are still not met. Once interference exceeds the level acceptable at that moment, a “complaint” is sent to the control center, a mobile or remote server for instance, and possibly further forwarded to a fixed gateway or another server for proper action. The server may then check a database or otherwise determine which setting is the best fit and advise the terminal to use the new setting for subsequent operation.
b. For active on-line coordination, depending on how aggressively statistical gain out of space multiplexing and other resources are to be utilized, run-time error detection and forecast may be performed using error history.

An example high-level coordination algorithm for combining error and congestion control is shown in FIG. 7 and has been described above. Coordination may be accomplished by having a remote system perform some of the method steps of FIG. 7 and send control signals to mobile terminals, for instance.

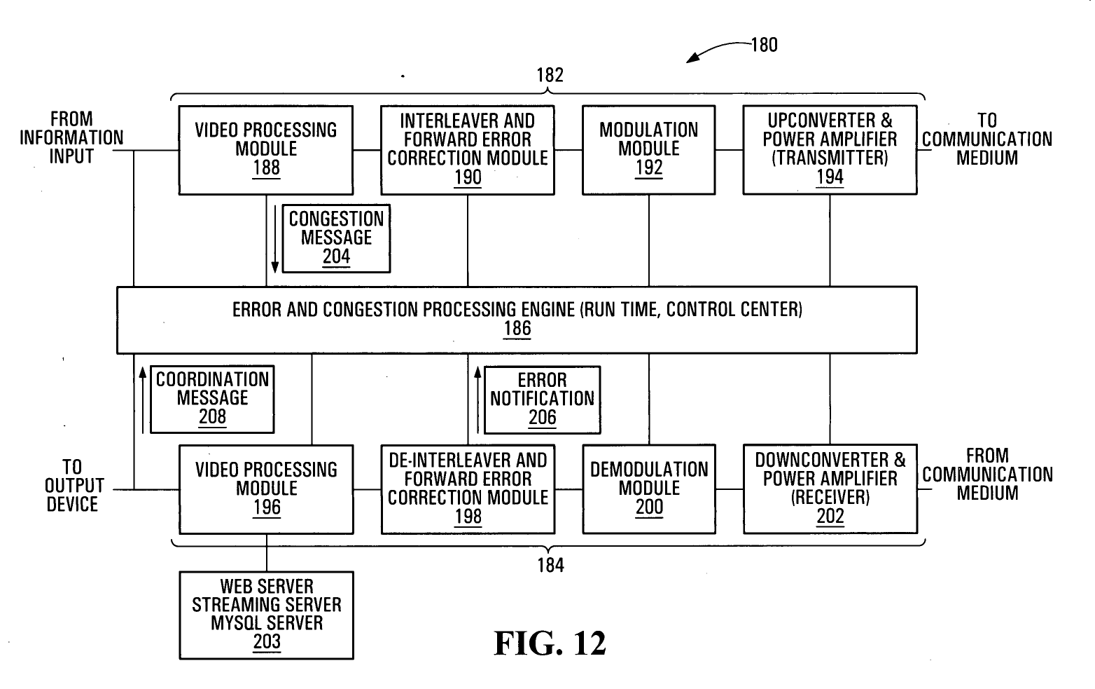

FIG. 12 shows a block diagram for a control center or server implementation corresponding to the terminal structure of FIG. 11. The system 180 of FIG. 12 is illustrative of one possible embodiment of the mobile and remote servers 24, 30 in FIG. 1. The gateway 18 is effectively a server of the servers 24, 30, and thus could be substantially similar in structure and operation to those servers. The gateway 18, however, would generally have stronger computation/storage capabilities and more interfacing to different networks than the other servers.

The system 180, like the terminal 150, includes a receive chain 182 having interconnected components 188, 190, 192, 194 and a transmit chain 184 having interconnected components 196, 198, 200, 202, but has a control center or server portion 186 of an error and congestion processing engine. Operation of the system 180 may be substantially similar to that of the terminal 150, although processing intensive operations may be performed to a greater extent by the engine 186 than the engine 156. As described above, a server would typically have higher processing power than a terminal, and accordingly the engine 186 may be configured to perform more extensive processing of its inputs 204, 206, 208, and others (not shown) to generate control outputs for use both locally by the server components and remotely, where a server also controls operation of the terminals it serves. The engine 186 may insert information for processing into the transmit chain 182 through the video processing module 188 as shown, or possibly at another point in the transmit chain.

Additional operations of a server which might not be performed by a terminal involve storage and/or distribution of received information for access by client systems. This is represented in FIG. 12 at 203, which lists a web server, streaming server, and MySQL server as illustrative examples of databases or systems through which information received from terminals may be made available for access.

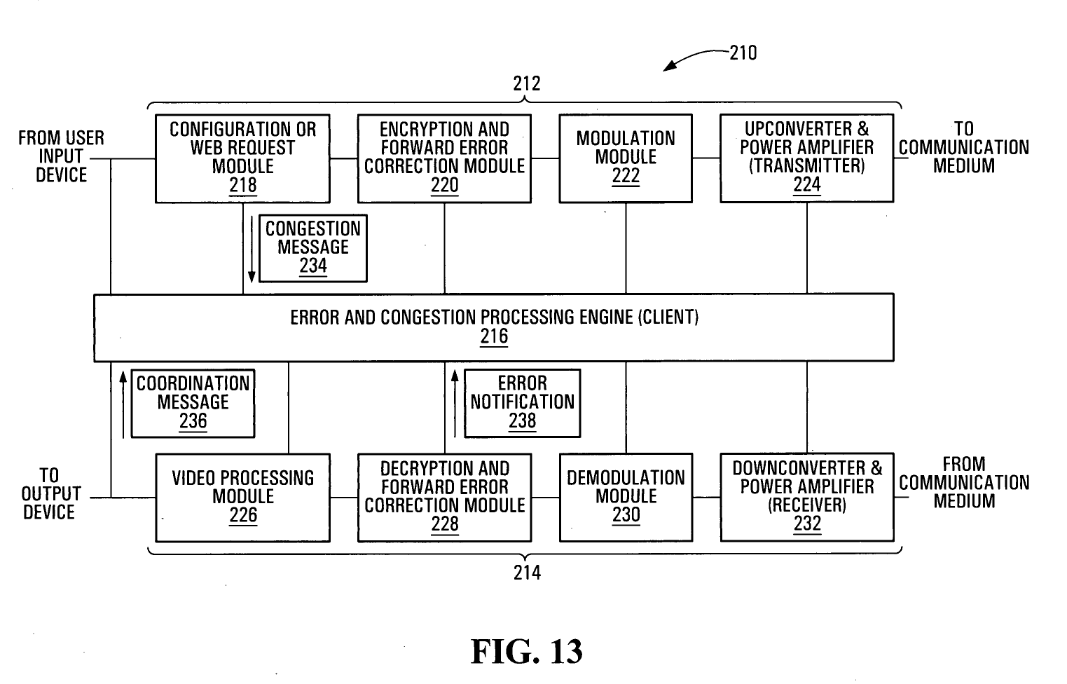

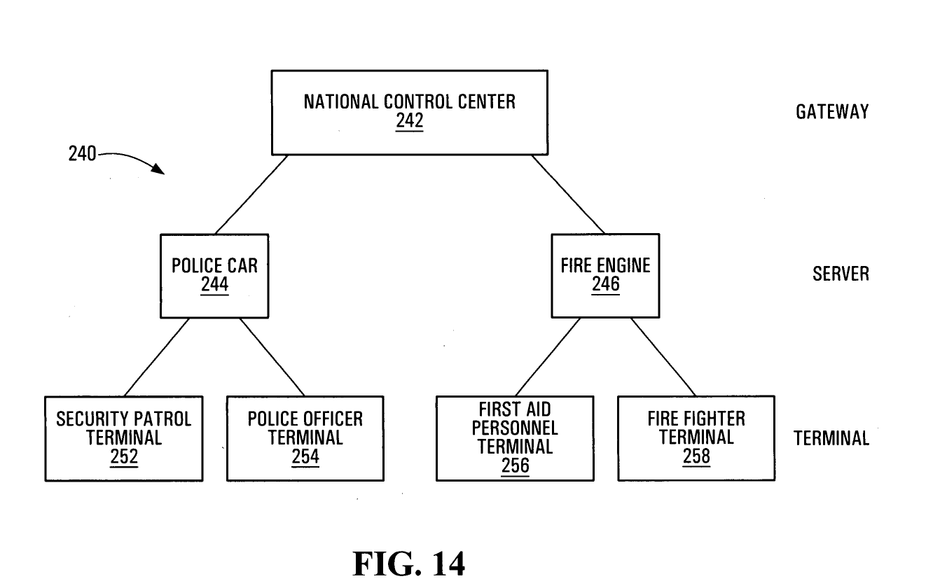

FIG. 13 is a block diagram of an example client system, in the format of FIGS. 11 and 12. The client system 210 includes transmit and receive chains 212 and 214 with interconnected components 218, 220, 222, 224 and 226, 228, 230, 232. Components of the transmit and receive chains 212, 214 are operatively coupled to a client error and congestion processing engine 216, which processes inputs 234, 236, 238, and possibly others, to provide control outputs for controlling the operation of transmit and receive chain components.

The overall structure of the client system 210 is similar to that of the terminal 150 (FIG. 11) and the server 180 (FIG. 12), although the client system 210 operates in a slightly different manner, to communicate with one or more servers, to access and display information collected by terminals, and to carry out some configure, command and coordination operations, for instance, responsive to user inputs, monitored control information, operating conditions, etc.

Any or all of the techniques described above may be applied to communications between the client system 210 and a server.

FIG. 12 shows an example video communication application of the techniques disclosed herein, for public safety authority usage. The system 240 includes a national control center 242 at the gateway level, a police car 244 and a fire engine 246 incorporating mobile servers at the server level, and mobile terminals 252, 254, 256, 258 which are carried by public safety personnel. The terminals 252, 254, 256, 258 gather information, illustratively video signals, which is transmitted in real time to the servers 244, 246 and then on to the national control center 242 for subsequent access by client systems (not shown).

Where a terminal, 252 for example, has an error declared to its error and congestion processing engine, the engine will prepare to “shift gear” to a longer mode interleave for instance through a control output to its interleaver module. This mode change may be subject to approval from the control center 244. In this case, the terminal 252 may send a request to its server 244 for an increase in interleaver length. The server 244 will then query its database (not shown) or its gateway 242, and possibly combine its own observations to decide if the request of increasing interleaver length should be granted. Once this determination is made, the terminal 252 is notified accordingly, and interleaver length is either maintained or increased.

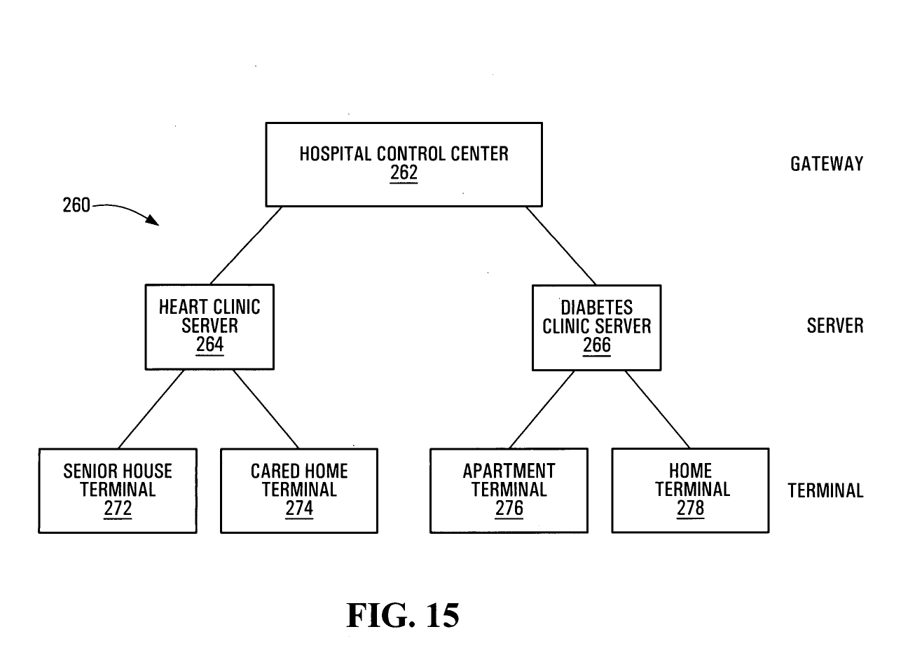

FIG. 15 shows another possible application of embodiments of the invention for tele-home care usage. In this example system 260, a hospital control center 262 at the gateway level is operatively coupled to a heart clinic server 264 and a diabetes clinic server 266, which respectively serve terminals 272, 274, 276, 278 at various locations. When terminals and servers are deployed at fixed locations, wired connections between a gateway, servers, and terminals may be feasible. The techniques disclosed herein may thus be applied to wired communication systems as well.

FIG. 16 is a block diagram of an example mobile terminal, including both wireless and video parts. Interleaving, encryption, and down-sampling are performed primarily in the video processor in FIG. 16. Some functions of the video processor may be performed in conjunction with the MSP microprocessor, for network layer related processing such as packet header filtering to distinguish control signals from video data, and the CPU for physical layer processes, such as power amplifier saturation warning.

According to an embodiment of the invention, terminals transmit information to a server, which performs corresponding de-interleaving, decryption, and up-sampling operations. These operations may thus be performed by a processor and other components of a personal computer, although other embodiments in which these functions are supported in a video processor or FPGA chip, for example, are also contemplated.

It should also be appreciated that the video processor, MSP, and CPU may support de-interleaving, decryption, and up-sampling at a terminal in some embodiments.

The techniques and systems described herein may be tested, for example, using computer-based simulation, actual field trial, or some combination thereof. Wireless channel models and Internet loss models, for instance, may be used to generate simulation graphs. For simplicity, a simulated system may include one control and command center, four wireless drop side cameras, one Internet remote controller, and another GPRS remote reviewer. As for field trial communications, wireless camera and control signals may be exchanged over a 900 MHz Frequency Hopping system, for example. In one test setup, a transmitter is mounted on a service truck, and subjective video quality tests for 1.3 Megapixel JPEG and QCIF (Quarter Common Intermediate Format, a 176×144 pixel video format)resolution MPEG4 are done with different driving speeds. The same performance test may be performed with a 1.9 GHz GPRS link at the reviewer end. Of course, other topologies and test methodologies may also be used.

What has been described is merely illustrative of the application of the principles of the invention. Other arrangements and methods can be implemented by those skilled in the art without departing from the scope of the present invention.

For example, many different types of implementations of embodiments of the invention are possible. Components or devices described as hardware above may alternatively be implemented partially or substantially in software. Similarly, method steps disclosed herein may be performed by hardware or implemented in software code.

Although the above description takes an example system with the over the air or land architecture, using adaptive multi-layer schemes, focusing on interleaving, the general principle applies to other architectures, such as underwater acoustic or Very Low Frequency (VLF) marine applications as well.

The concepts can be further applied to nuclear submarine or deep space systems, such as particle communication system using sub-nucleus inter-star imaging systems. For example, part of pre-interleave may be applied before sending information through a neutrino system, where the particle can penetrate the entire earth with almost no loss of energy. The information can be modulated on to the sub-neutron particles based on their energy level or left or right spinning characteristics.

The concept also applies to co-existing systems, such as satellite systems with terrestrial wireless systems. For example, part of pre-interleave may be applied before sending signals through satellite or GPRS system, without increase any overhead.

Embodiments of the invention are of immediate applicability to narrowband wireless, wired or underwater acoustic applications, but could be used in any type of other communication including HomePlug, satellite systems and particle communications, to:
Increase the robustness of the link by using multi layer Fractal interleaving scheme;
Increase the reliability within a network by using automated run-time error recognition; and/or
Improve the final video quality by using adaptive dynamic cross layer coordination.

Further advantages of embodiments of the invention will also be apparent from the above description and the appended claims.

### REFERENCES

[Amir] M. R. Yazdani and A. H. Banihashemi, “On Construction of Rate-Compatible Low-Density Parity-Check Codes,” IEEE Comm. Letters, vol. 8, no. 3, pp. 159-161, March 2004.
[Barbeau] M. Barbeau, F. Bordeleau and Jeff Smith, “An introduction to a UML platform independent model of a software radio”, ICT, Beijing, 2002.
[Booch] G. Booch, J. Rumbaugh and I. Jacobson, The Unified Modeling Language User Guide, Addison Wesley, 1999.
[Bruce] Bruce R. Elbert, The Satellite Communication Applications Handbook, Artech House Publishers, 2004.
[Cai] Jianfei Cai and Chang Wen Chen, “Use of pre-interleaving for video streaming over wireless access networks”, Proceedings of International Conference on Image Processing, vol. 1, p. 934-937, 2001.
[Chakravorty] R. Chakravorty, A. CLark and I. Pratt, “GPRSWeb: Optimizing the Web for GPRS Links”, Proceedings of ACM First Mobile Systems, Applications and Services Conference (ACM Mobisys 2003), May 2003.
[Claypool] Mark Claypool and Yali Zhu. “Using Interleaving to Ameliorate the Effects of Packet Loss in a Video Stream”, In Proceedings of the International Workshop on Multimedia Network Systems and Applications (MNSA), Providence, R.I., USA, May 2003.
[Ding] Gang Ding, Halima Ghafoor and Bharat Bhargava, “Error Resilient Video Transmission over Wireless Networks”, in The 6th IEEE International Symposium on Object-oriented Real-time Distributed Computing, Hakodate, Japan, May 2003.
[Hatim] Hatim Zaghloul et al , “Wide-band Orthogonal Frequency Division Multiplexing (W-OFDM) and Multi-code Direct Sequence Spread Spectrum (MC-DSSS)” Wi-LAN patent, 1992.
[Hanzo] L. Hanzo, T. H. Liew, B. L. Yeap, “Turbo Coding, Turbo Equalisation and Space-Time Coding for Transmission over Fading Channels,” John Wiley & Sons Canada, Ltd., 2002.
[He] Y. W. He, S. Q. Yang, Y. Z. Zhong, “Block-based Fine Granularity Scalable Video Coding for Content-Aware Streaming”, ICIP'2002, Sep. 22-25, 2002, USA.
[Huang] C. R. Baugh, J. Huang, “Traffic model for IEEE802.16 TG3 Mac/Phy simulations”, http://ieee802.org/16, 2001.
[James] James Gross and Andreas Willig. “Measurements of a wireless link in different RF-isolated environments”. In Proc. European Wireless 2002 (EW2002), February 2002.
[Jerding] D. F. Jerding, J. T. Stasko and T. Ball, “Visualizing Interactions in Program Executions,” Proc. ACM International Conference on Software Engineering (ICSE), Boston, Mass., pp. 360-370, 1997.
[Jiang] Bo Jiang, “Voice Performance Evaluation of BLUETOOTH System in the Presence of WLAN IEEE802.11b System”, Master thesis, School of Information Technology and Engineering, University of Ottawa, 2003.
[Kern] J. Kern, “Sequence Diagram Generation—Effective Use of Options,” TogetherSoft, White Paper, 2001.
[Kollmann] R. Kollmann and M. Gogolla, “Capturing Dynamic Program Behaviour with UML Collaboration Diagrams,” Proc. IEEE European Conference on Software Maintenance and Reengineering, Lisbon, Portugal, pp. 58-67, 2001.
[Raman] A. Raman and M. Babu, “A Low Complexity Error Concealment Scheme For MPEG4 Coded Video Sequences,” 10th Symposium on Multimedia Communications and Signal Processing, Bangalore, India, November 2001.
[Richer] T. Richner and S. Ducasse, “Using Dynamic Information for the Iterative Recovery of Collaborations and Roles,” Proc. IEEE International Conference of Software Maintenance (ICSM), Montreal, Quebec, pp. 34-43, 2002.
[Robert] Robert H. Morelos-Zaragoza, The Art of Error Correcting Coding, John Wiley & Sons Canada, Ltd., 2002.
[Masami] AIZAWA, MASAMI and OKITA, SHIGERU, “TRANSMISSION SYSTEM AND APPARATUS THEREFOR,” CIPO Patent 2153956, 1995.
[Muharemovic] T. Muharemovic, A. Gatherer, W. Ebel, S. Srihosour, D. Hocevar , E. Huang, “Space-Time Codes with Bit Interleaving,” Globecom, (November 2001).
[Preissig] R. Stephen Preissig, “Data Encryption Standard (DES) Implementation on the TMS320C6000”, www.ti.com, 2000.
[Supavadee] Supavadee Aramvith, Chia-Wen Lin, Ming-Ting Sun, “Wireless Video Transport Using Conditional Retransmission and Low-Delay Interleaving”, 11th International Packet Video Workshop, 30 Apr.-1 May 2001.
[Stojanovic] M. Stojanovic, J. Catipovic and J. Proakis, “Reduced Complexity Spatial and Temporal Processing of Underwater Acoustic Communication Signals,” Journal of the Acoustical Society of America, vol. 98 (2), Pt. 1, August 1995, pp. 961-972.
[STRIKE] STRIKE, “4G scenarios and system requirements”, European Commission, Information Society Technologies, 2001.
[Systa] T. Systa, K. Koskimies and H. Muller, “Shimba—An Environment for Reverse Engineering Java Software Systems,” Software—Practice and Experience, vol. 31 (4), pp. 371-394, John Wiley & Sons, 2001.
[Vucetic] Branka Vucetic, Jinhong Yuan, “Space-Time Coding”, John Wiley & Sons Canada, Ltd., 2003.
[Walker] R. J. Walker, G. C. Murphy, B. Freeman-Benson, D. Wright, D. Swanson and J. Isaak, “Visualizing Dynamic Software System Information through High-Level Models,” Proc. ACM SIGPLAN Conference on Object-Oriented Programming, Systems, Languages and Applications (OOPSLA), Vancouver, B.C., pp. 271-283, 1998.
[Xueshi] Xueshi Yang, A. P. Petropulu, “Joint statistics of interference in a wireless communication link resulted from a Poisson field of interferers”, IEEE International Conference on Acoustics, Speech and Signal Processing (ICASSP), Orlando, Fla., May 2002.
[Yu] O. Yu and S. Khanvilkar, “QoS provisioning over GPRS wireless mobile links”, IEEE WCNC2002, vol: 1, pp: 322-326, March 2002.

1. An interleaving system comprising:
an input for receiving information; and
a plurality of interleavers operatively coupled to the input in an interleaving path, the plurality of interleavers having respective associated interleaving lengths and being configured to interleave the received information according to their respective associated interleaving lengths to provide an aggregate interleaving length for the interleaving path.

2. The system of claim 1, further comprising:
a controller configured to control whether each of the plurality of interleavers is active in the interleaving path to interleave the received information.

3. The system of claim 2, further comprising
a receiver operatively coupled to the controller and configured to receive control information,
wherein the controller is configured to control whether each of the interleavers is active based on the received control information.

4. The system of claim 3, wherein the control information comprises at least one of: monitored communication link information for a communication link over which the information is to be transmitted and a command to activate an interleaver having a particular associated length.

5. The system of claim 1, wherein the interleaving lengths follow a discrete Fractal distribution.

6. The system of claim 2, wherein the controller is configured to control whether each of the interleavers is active based on a type of the received information.

7. The system of claim 6, wherein the controller is configured to control the interleavers to provide a first aggregate interleaving length where the information comprises still images and a second aggregate interleaving length shorter than the first interleaving length where the information comprises video.

8. The system of claim 1, wherein the plurality of interleavers comprises interleavers respectively associated with different layers in a layered architecture.

9. A communication device comprising the system of claim 1, the communication device being configured to transmit interleaved information.

10. The communication device of claim 9, further comprising:
a transmitter operatively coupled to the interleaving system for transmitting the interleaved information to a remote system;
a receiver configured to receive control information from the remote system; and
a controller operatively coupled to the interleaving system and to the receiver, and configured to control whether each of the plurality of interleavers is active in the interleaving path to interleave the received information based on the control information received from the remote system.

11. The system of claim 1, further comprising:
an input for receiving security information,
wherein the plurality of interleavers comprises at least one interleaver which is further configured to interleave the information based on the received security information.

12. A de-interleaving system comprising:
an input for receiving interleaved information; and
a plurality of de-interleavers operatively coupled to the input in a de-interleaving path, the plurality of de-interleavers having respective associated de-interleaving lengths and being configured to de-interleave the received interleaved information according to their respective associated de-interleaving lengths to provide an aggregate de-interleaving length for the de-interleaving path.

13. The system of claim 12, further comprising:
an input for receiving security information,
wherein the plurality of de-interleavers comprises at least one de-interleaver which is further configured to de-interleave the received interleaved information based on the received security information.

14. The system of claim 12, further comprising:
a controller configured to control whether each of the plurality of de-interleavers is active in the de-interleaving path to de-interleave the received interleaved information,
wherein the controller is further configured to determine an interleaving length used at a source of the received interleaved information, and to control the de-interleavers to provide an aggregate de-interleaving length corresponding to the interleaving length.

15. A method of processing information, comprising:
receiving information over a communication link;
analyzing the received information to determine conditions on the communication link; and
interleaving information to be subsequently transmitted on the communication link using an adapted interleaving length, the adapted interleaving length being determined on the basis of the determined conditions.

16. The method of claim 15, wherein analyzing comprises determining whether the information comprises an expected sequence value.

17. The method of claim 15, further comprising:
detecting congestion of the communication link; and
determining the adapted interleaving length responsive to detecting congestion.

18. The method of claim 15, further comprising:
receiving information to be transmitted on the communication link;
interleaving the information to be transmitted using the adapted interleaving length; and
transmitting on the communication link the interleaved information and an indication of the adapted interleaving length.

19. An interleaving system comprising:
an input for receiving information;
an input for receiving security information; and
at least one interleaver configured to receive the information and the security information, and to interleave the received information using the received security information, the at least one interleaver controlling respective interleaved positions of portions of the received information based on the received security information.

20. The system of claim 19, wherein the at least one interleaver comprises a plurality of interleavers configured to interleave the received information based on respective portions of the received security information.

21. A de-interleaving system comprising:
an input for receiving interleaved information;
an input for receiving security information; and
at least one de-interleaver configured to receive the interleaved information and the security information, and to de-interleave the received interleaved information using the received security information, the at least one de-interleaver controlling respective positions of portions of the received interleaved information in a de-interleaved data stream based on the received security information.

22. A method of encrypting information, comprising:
receiving information;
receiving an encryption key; and
interleaving the received information based on the encryption key to generate interleaved information, the respective interleaved positions of a plurality of portions of the received information in the interleaved information being determined by the encryption key.
